(19) United States
(12) Patent Application Publication
(10) Pub. No.: US 2026/0026213 A1
(43) Pub. Date: Jan. 22, 2026

(54) DISPLAY MODULE AND ELECTRONIC DEVICE INCLUDING THE SAME

(71) Applicant: Samsung Display Co., LTD., Yongin-si (KR)

(72) Inventors: GYEONG YUN CHO, Yongin-si (KR); JAE-MO CHUNG, Yongin-si (KR)

(21) Appl. No.: 19/061,541

(22) Filed: Feb. 24, 2025

(30) Foreign Application Priority Data
Jul. 17, 2024 (KR) 10-2024-0094528

(51) Int. Cl. H10K 59/126; H10K 59/131

(52) U.S. Cl. CPC H10K 59/126; H10K 59/131

(57) ABSTRACT

A display module includes a base member, a plurality of shielding lines and a shielding pattern. The base member is defined with a first area, a second area and a third area. The second area is bent. The plurality of shielding lines overlaps with the second area. The shielding pattern overlaps with the second area and is electrically connected to the shielding lines. Electromagnetic interference generated from the second area is blocked by the plurality of shielding lines and the shielding pattern.

This application claims priority to Korean Patent Application No. 10-2024-0094528, filed on Jul. 17, 2024, and all the benefits accruing therefrom under 35 U.S.C. § 119, the content of which in its entirety is herein incorporated by reference.

### BACKGROUND

### 1. Field

The disclosure relates to a display module and an electronic device, and more specifically to a display module and an electronic device including a shielding line and a shielding pattern to block electromagnetic interference occurring in a bending area of the display module.

### 2. Description of the Related Art

Increasing a ratio of a display area occupancy in a display device is advantageous in various features. It is advantageous in providing a broader display area when the size of a display device is the same, and it is advantageous in making a display device smaller and lighter when the size of a display area is the same. Therefore, various efforts have been made to increase the ratio of a display area occupancy in a display device.

For example, the display module may be provided with a foldable or bendable bending area between an image display area for displaying an image and an operation area for processing information for displaying an image and input information. In addition, as the bending area is folded backwards, the operation area may be disposed at the rear of the image display area so that the area of the display device is decreased while the area of the display area is maintained.

As the result, the ratio of the display area in the display device may be increased.

### SUMMARY

However, in the above case, electromagnetic interference may be occurred due to electric signals exchanged between the operation area and the image display area. Particularly, in the case where electromagnetic interference occurs in the bending area, it may be difficult to apply means for blocking electromagnetic interference, such as a conductive tape. Therefore, it may be difficult to position other elements in front of the bending area due to electromagnetic interference occurred in the bending area. Specifically, in the case where an element such as a radio wave communication module is disposed in front of the bending area, electromagnetic waves occurred in the bending area may serve as a noise in the radio wave communication module, disabling the normal operation of the radio wave communication module.

Therefore, there is a need for a method for blocking electromagnetic interference occurred in the bending area.

A feature of the disclosure is to provide a display module and an electronic device including a shielding line and a shielding pattern configured to block electromagnetic interference occurred in a bending area of the display module.

A display module in an embodiment of the disclosure may include a base member, a plurality of light-emitting components, a plurality of first lines, a plurality of second lines, a first circuit insulating layer, a plurality of shielding lines, a second circuit insulating layer, and a shielding pattern.

In the base member, a first area including a display area and a non-display area surrounding the display area, a second area extending from the first area, and a third area extending from the second area may be defined, and the second area may be bent.

In an embodiment, the plurality of light-emitting components may be disposed on the base member and may overlap with the display area.

In an embodiment, the plurality of first lines may be disposed on the base member and may overlap with the first area.

In an embodiment, the plurality of second lines may be disposed on the base member, may overlap with the third area, and may correspond, respectively, to the plurality of first lines.

In an embodiment, the first circuit insulating layer may be disposed on the base member and may cover the plurality of first lines and the plurality of second lines. The first circuit insulating layer may overlap with the first area, the second area, and the third area. The first circuit insulating layer may be defined with a plurality of first contact holes.

In an embodiment, the plurality of shielding lines may be disposed on the first circuit insulating layer and overlap with the second area. The plurality of first lines may be electrically connected to the plurality of second lines, respectively, through the plurality of first contact holes.

In an embodiment, the second circuit insulating layer may be disposed on the first circuit insulating layer and may cover the plurality of shielding lines. The second circuit insulating layer may overlap with the first area, the second area, and the third area. The second circuit insulating layer may be defined with a plurality of second contact holes.

In an embodiment, the shielding pattern may be disposed on the second circuit insulating layer. The shielding pattern may overlap with the second area. The shielding pattern may be electrically connected to the plurality of shielding lines through the plurality of second contact holes.

In an embodiment, some of the plurality of second contact holes may overlap with the first area, and the rest of the plurality of second contact holes may overlap with the third area.

In an embodiment, the display module may further include a plurality of input sensor electrodes disposed on the plurality of light-emitting components. Two input sensor electrodes next (adjacent) to each other among the plurality of input sensor electrodes may form a capacitor. A material contained in each of the plurality of input sensor electrodes may be the same as the material contained in the shielding pattern.

In an embodiment, the display module may further include a plurality of pixel circuits, a scan driving unit, a plurality of scan driving unit control lines, a plurality of data lines, a plurality of power lines, and a plurality of input sensor lines.

In an embodiment, the plurality of pixel circuits may be electrically connected to the plurality of light-emitting components.

In an embodiment, the scan driving unit may provide a scan signal to the plurality of pixel circuits.

In an embodiment, the plurality of scan driving control lines may transfer an electrical signal for controlling the scan driving unit.

In an embodiment, the plurality of data lines may transfer the data signal to the plurality of pixel circuits.

In an embodiment, the plurality of power lines may transfer the power to the plurality of pixel circuits.

In an embodiment, the plurality of input sensor lines may be electrically connected to the plurality of input sensor electrodes.

In an embodiment, the shielding pattern may overlap with at least one of the plurality of scan driving unit control lines, the plurality of data lines, and the plurality of input sensor lines.

In an embodiment, the shielding pattern may not overlap with the plurality of power lines.

In an embodiment, the plurality of shielding lines may include a first shielding line, a second shielding line, a third shielding line, a fourth shielding line, a fifth shielding line, and a sixth shielding line.

In an embodiment, the second shielding line may be disposed parallel to the first shielding line, with the plurality of scan driving unit control lines interposed therebetween.

In an embodiment, the third shielding line may be spaced apart from the second shielding line.

In an embodiment, the fourth shielding line may be disposed parallel to the third shielding line, with the plurality of data lines interposed therebetween.

In an embodiment, the fifth shielding line may be spaced apart from the fourth shielding line.

In an embodiment, the sixth shielding line may be disposed parallel to the fifth shielding line, with the plurality of input sensor lines interposed therebetween.

In an embodiment, the shielding pattern may include a first shielding pattern, a second shielding pattern, and a third shielding pattern.

In an embodiment, the first shielding pattern may overlap with the plurality of scan driving unit control lines.

In an embodiment, the second shielding pattern may overlap with the plurality of data lines and may be spaced apart from the first shielding pattern.

In an embodiment, the third shielding pattern may overlap with the plurality of input sensor lines and may be spaced apart from the first shielding pattern and the second shielding pattern.

In an embodiment, a voltage applied to the first shielding pattern may be higher than a minimum voltage applied to the plurality of scan driving unit control lines and lower than a maximum voltage applied to the plurality of scan driving unit control lines.

In an embodiment, a voltage applied to the second shielding pattern may be higher than a minimum voltage applied to the plurality of data lines and lower than a maximum voltage applied to the plurality of data lines.

In an embodiment, a voltage applied to the third shielding pattern may be higher than a minimum voltage applied to the plurality of input sensor lines and lower than a maximum volage applied to the plurality of input sensor lines.

In an embodiment, each of the plurality of pixel circuits may include a transistor including a first electrode, a second electrode, and a control electrode. A material included in each of the first electrode and the second electrode may be the same as the material included in each of the plurality of shielding lines.

In an embodiment, the shielding pattern may include a plurality of shielding pattern lines. Each of the plurality of shielding pattern lines may have at least a portion extending in a direction intersecting with the plurality of shielding lines.

In an embodiment, the display module may further include an inorganic insulating layer and a sub-shielding pattern. The inorganic insulating layer may cover the shielding pattern, overlap with the first area, the second area, and the third area, and be defined with a plurality of third contact holes.

In an embodiment, the sub-shielding pattern may be disposed on the inorganic insulating layer. The sub-shielding pattern may overlap with the second area. The sub-shielding pattern may be electrically connected to the shielding pattern through the plurality of third contact holes.

In an embodiment, the plurality of third contact holes may overlap with at least one of the first area, the second area, and the third area.

In an embodiment, the display module in another embodiment of the disclosure may include a base member, a plurality of light-emitting components, a plurality of first lines, a plurality of second lines, a plurality of shielding lines, and a shielding pattern.

In an embodiment, the base member may be defined with a first area including a display area and a non-display area surrounding the display area, a second area extending from the first area, and a third area extending from the second area.

In an embodiment, the plurality of light-emitting components may be disposed on the base member and overlap with the display area.

In an embodiment, the plurality of first lines may be disposed on the base member and disposed on a first plane parallel to the first area. The first plane may correspond to the first area.

In an embodiment, the plurality of second lines may be disposed on the base member and disposed on a second plane parallel to the third area. The second plane may correspond to the third area. Each of the plurality of second lines may correspond to the plurality of first lines.

In an embodiment, the shielding lines may be disposed on a third plane on the first plane. The third plane may correspond to the second area. The shielding lines may electrically connect the plurality of first lines to the plurality of second lines, respectively.

In an embodiment, the shielding patterns may be disposed on a fourth plane on the third plane. The fourth plane may correspond to the second area and include a shielding pattern electrically connected to the plurality of shielding lines.

In an embodiment of, the shielding pattern may extend in a direction intersecting with the third plane in the first area to contact the plurality of shielding lines. The shielding pattern may extend in a direction intersecting with the third plane in the third area to contact the plurality of shielding lines.

In an embodiment, the display module may further include a plurality of input sensor electrodes disposed on the plurality of light-emitting components.

In an embodiment, two input sensor electrodes next (adjacent) to each other among the plurality of input sensor electrodes may form a capacitor.

In an embodiment, a material included in each of the plurality of input sensor electrodes may be the same as the material included in the shielding pattern.

In an embodiment, the display module may further include a plurality of pixel circuits, a scan driving unit, a plurality of scan driving unit control lines, a plurality of data lines, a plurality of power lines, and a plurality of input sensor lines.

In an embodiment, the plurality of pixel circuits may be electrically connected to the plurality of light-emitting components.

In an embodiment, the scan driving unit may provide a scan signal to the plurality of pixel circuits.

In an embodiment, the plurality of scan driving unit control lines may transfer an electrical signal for controlling the scan driving unit.

In an embodiment, the plurality of data lines may transfer a data signal to the plurality of pixel circuits.

In an embodiment, the power lines may transfer power to the plurality of pixel circuits.

In an embodiment, the plurality of input sensor lines may be electrically connected to the plurality of input sensor electrodes.

In an embodiment, the shielding pattern may overlap with at least one of the plurality of scan driving unit control lines, the plurality of data lines, and the plurality of input sensor lines.

In an embodiment, the plurality of shielding lines may include a first shielding line, a second shielding line, a third shielding line, a fourth shielding line, a fifth shielding line, and a sixth shielding line.

In an embodiment, the second shielding line may be disposed parallel to the first shielding line, with the plurality of scan driving unit control lines interposed therebetween.

In an embodiment, the third shielding line may be spaced apart from the second shielding line.

In an embodiment, the fourth shielding line may be disposed parallel to the third shielding line, with the plurality of data lines interposed therebetween.

In an embodiment, the fifth shielding line may be spaced apart from the fourth shielding line.

In an embodiment, the sixth shielding line may be disposed parallel to the fifth shielding line, with the plurality of input sensor lines interposed therebetween.

In an embodiment, the shielding pattern may include a first shielding pattern, a second shielding pattern, and a third shielding pattern.

In an embodiment, the first shielding pattern may overlap with the plurality of scan driving unit control lines.

In an embodiment, the second shielding pattern may overlap with the plurality of data lines and may be spaced apart from the first shielding pattern.

In an embodiment, the third shielding pattern may overlap with the plurality of input sensor lines and may be spaced apart from the first shielding pattern and the second shielding pattern.

In an embodiment, each of the plurality of pixel circuits may include a transistor including a first electrode, a second electrode, and a control electrode.

In an embodiment, a material included in each of the first electrode and the second electrode may be the same as the material included in each of the plurality of shielding lines.

In an embodiment, the shielding pattern may include a plurality of shielding pattern lines. Each of the plurality of shielding pattern lines may have at least a portion extending in a direction intersecting with the plurality of shielding lines.

In an embodiment, the display module may further include a sub-shielding pattern.

In an embodiment, the sub-shielding pattern may be disposed on a fifth plane defined on the fourth plane. The sub-shielding pattern may correspond to the second area. The sub-shielding pattern may be electrically connected to the shielding pattern.

In an embodiment, the sub-shielding pattern may extend in a direction intersecting with the fourth plane in at least one of the first area, the second area, and the third area to contact the shielding pattern.

In an embodiment, the electronic device in may include a display module and a communication module.

In an embodiment, the display module may include a base member, a plurality of light-emitting components, a plurality of first lines, a plurality of second lines, a first circuit insulating layer, a plurality of shielding lines, a second circuit insulating layer, and a shielding pattern.

In an embodiment, the base member may be defined with a first area including a display area and a non-display area surrounding the display area, a second area extending from the first area, and a third area extending from the second area. The second area may be bent.

In an embodiment, the plurality of light-emitting components may be disposed on the base member and overlap with the display area.

In an embodiment, the plurality of first lines may be disposed on the base member and overlap with the first area.

In an embodiment, the plurality of second lines may be disposed on the base member and overlap with the third area. The plurality of second lines may correspond to the plurality of first lines, respectively.

In an embodiment, the first circuit insulating layer may be disposed on the base member and cover the plurality of first lines and the plurality of second lines. The first circuit insulating layer may overlap with the first area, the second area, and the third area and may be defined with a plurality of first contact holes.

In an embodiment, the plurality of shielding lines may be disposed on the first circuit insulating layer and overlap with the second area. The plurality of shielding lines may electrically connect the plurality of first lines to the plurality of second lines through the plurality of first contact holes.

In an embodiment, the second circuit insulating layer may be disposed on the first circuit insulating layer and cover the plurality of shielding lines. The second circuit insulating layer may overlap with the first area, the second area, and the third area and may be defined with a plurality of second contact holes.

In an embodiment, the shielding pattern may be disposed on the second circuit insulating layer and overlap with the second area. The shielding pattern may be electrically connected to the plurality of shielding lines through the plurality of second contact holes.

In an embodiment, the plurality of shielding lines and the shielding pattern may be interposed between the communication module and the base member.

In an embodiment of the disclosure, by including the shielding line and the shielding pattern, it become possible to block electromagnetic interference occurring in the bending area of the display module.

Accordingly, it becomes possible to provide a display device without malfunction even when the front of the bending area of the display module is disposed with a diode that is sensitive to electromagnetic interference.

### BRIEF DESCRIPTION OF THE DRAWINGS

These and/or other features will become apparent and more readily appreciated from the following description of the embodiments, taken in conjunction with the accompanying drawings in which:

FIG. 1A is an exemplary perspective view of an embodiment of a display device according to the disclosure;

FIG. 1B is an exemplary exploded perspective view of an embodiment of a display device according to the disclosure;

FIG. 2A is an exemplary illustration of a partial cross-section taken along line I-I′ of FIG. 1;

FIG. 2B is an exemplary illustration of a partial cross-section taken along line I-I′ of FIG. 1;

FIG. 3 is an exemplary illustration of an embodiment of a display module according to the disclosure;

FIG. 4 is an exemplary plan view of an embodiment of a display module according to the disclosure;

FIG. 5 is an exemplary illustration of a partial cross-section taken along line II-II′ of FIG. 1;

FIG. 6 is an illustration of an equivalent circuit of an embodiment of a pixel according to the disclosure;

FIG. 7A is an exemplary illustration of an upper surface of a gate insulating layer in an area corresponding to section AA shown in FIG. 5;

FIG. 7B is an exemplary illustration of an upper surface of a first circuit insulating layer in an area corresponding to section AA shown in FIG. 5;

FIG. 7C is an exemplary illustration of an upper surface of a second circuit insulating layer in an area corresponding to section AA shown in FIG. 5;

FIG. 7D is an exemplary illustration of a plurality of shielding lines and a shielding pattern on the same plane in an area corresponding to section AA shown in FIG. 5;

FIG. 8 is an exemplary illustration of a partial cross-section taken along line III-III′ of FIG. 7D;

FIG. 9 is an exemplary illustration of a plurality of shielding lines and a shielding pattern on the same plane in an area corresponding to section AA shown in FIG. 5;

FIG. 10 is an exemplary illustration of a plurality of shielding lines and a shielding pattern on the same plane in an area corresponding to section AA shown in FIG. 5;

FIG. 11 is an exemplary illustration of a plurality of shielding lines and a shielding pattern on the same plane in an area corresponding to section AA shown in FIG. 5;

FIG. 12 is an exemplary illustration of a plurality of shielding lines and a shielding pattern on the same plane in an area corresponding to section AA shown in FIG. 5;

FIG. 13 is an exemplary illustration of a partial cross-section taken along line III-III′ of FIG. 7D;

FIG. 14 is an exemplary illustration of a partial cross-section taken along line III-III′ of FIG. 7D; and

FIG. 15 is a block diagram illustrating an electronic device according to an embodiment.

FIGS. 16 and 17 are diagrams illustrating electronic devices to which the display device according to an embodiment of the present disclosure is applied.

### DETAILED DESCRIPTION

References will now be made in detail to illustrative embodiments, of which examples are illustrated in the accompanying drawings, where like reference numerals refer to like elements throughout. The embodiments may have a variety of forms and permutations, but the disclosure shall by no means be construed as being limited to the described embodiments. Rather, the disclosure shall be construed to encompass all forms, permutations, equivalents and substitutes covered by the technical ideas and scope of the disclosure. Accordingly, the embodiments are merely described below, by referring to the drawing figures, to explain features of the disclosure.

Like or identical reference numerals refer to like or identical elements. Moreover, in the accompanying drawings, the thicknesses, ratios, and dimensions of the elements may not be to exact scale and may have been exaggerated for the benefit of effective explanation of the technical features associated with these elements. As such, the disclosure shall not be restricted to the thicknesses, ratios, dimensions, etc. illustrated in the drawings.

When an element is described to be “disposed on,” “placed on,” “arranged on,” “connected to,” or “coupled to” another element, it shall be construed as being disposed on, placed on, arranged on, connected to, or coupled to the other element directly but also as possibly having another element therebetween. When one element is described to be “directly disposed on,” “directly placed on,” “directly arranged on,” “directly connected to,” or “directly coupled to” another element, it shall be construed that there is no other element interposed therebetween.

Moreover, relative terms, such as “below,” “under,” “beneath,” “lower,” “bottom,” “above,” “over,” “upper,” “top,” etc., may be used herein to describe one element's relationship to another element as illustrated in the accompanying drawing figures. It shall be understood that relative terms are intended to encompass different orientations of the device in addition to the orientation depicted in the accompanying drawing figures. For example, if the device in one of the drawing figures is turned over, elements described as being on the “lower” side of the other elements would then be oriented on “upper” sides of the other elements. The exemplary term “lower” may therefore encompass an orientation of both “lower” and “upper,” depending on the particular orientation of the figure. Similarly, when the device in one of the drawing figures is turned over, elements described as “below” or “beneath” other elements would then be oriented “above” the other elements. The exemplary term “below” or “beneath” may therefore encompass an orientation of both above and below.

Furthermore, when one device or layer is described to be “on,” “over,” “above,” and the like, another device or layer, it shall also encompass the case of yet another device or layer disposed on, over, above, and the like, the other device or layer or interposed between the one device or layer and the other device or layer. On the contrary, when one device or layer is described to be “directly on,” “directly over,” “directly above,” and the like, another device or layer, it shall mean that no other device or layer is interposed between the one device or layer and the other device or layer.

An expression such as “comprising” or “including” is intended to designate a characteristic, a number, a step, an operation, an element, a part or combinations thereof, and shall not be construed to preclude any possibility of presence or addition of one or more other characteristics, numbers, steps, operations, elements, parts or combinations thereof.

Unless otherwise defined, all terms, including technical terms and scientific terms, used herein have the same meaning as how they are generally understood by those of ordinary skill in the art to which the disclosure pertains. Any term that is defined in a general dictionary shall be construed to have the same meaning in the context of the relevant art, and, unless otherwise defined explicitly, shall not be interpreted to have an idealistic or excessively formalistic meaning.

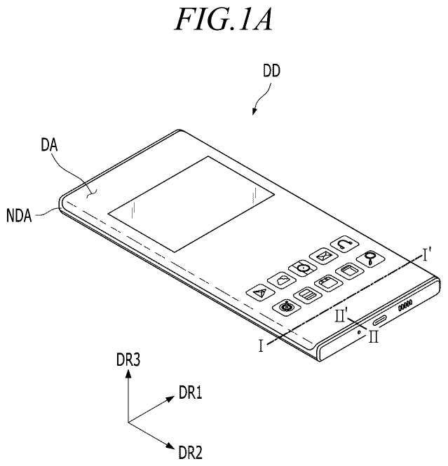

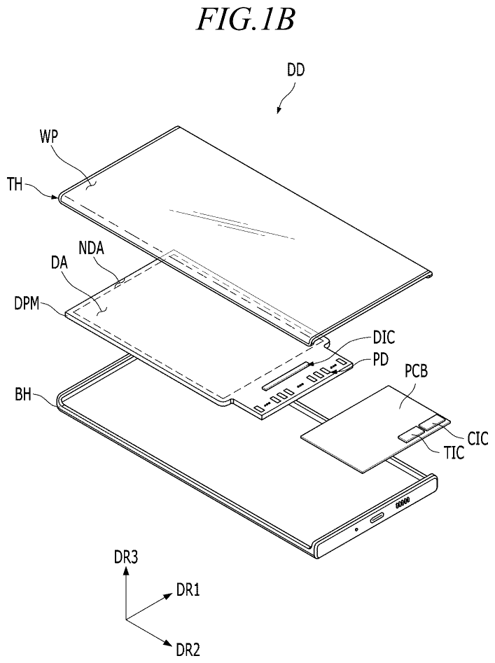

When an element is described to “overlap with” another element, the element is disposed in a normal direction of a surface of the other element, which is not limited to being disposed above or below a plane. FIG. 1A is an exemplary perspective view of a display device DD according to the disclosure. FIG. 1B is an exemplary exploded perspective view of a display device according to the disclosure.

FIG. 1A illustrates that a display device DD is implemented as an electronic device such as a smartphone. However, the purpose of the display device DD is not limited to what is illustrated in the figure. In an embodiment, the display device DD may be implemented as an electronic devices such as a tablet personal computer (“PC”), a laptop, a television, a head-mounted display, or a digital watch, for example.

Furthermore, the display device DD may be a part of a transportation means, such as a car, bicycle, motorcycle, train, boat, or airplane. In an embodiment, the display device DD may be disposed, relative to a driver of a vehicle, in front of the steering wheel in the vehicle and used for displaying instrument panel information such as the vehicle's speed, for example. The display device DD may be also disposed on the dashboard of a vehicle to display control interfaces, audio settings, temperature, road conditions, or video information. The display device DD may be disposed on either side of the driver's seat and the passenger seat and used as digital side rear-view mirrors. The display device DD may display images captured from the vehicle's exterior. The display device DD may be disposed (e.g., mounted) on the back of the driver's and passenger's seats, i.e., a side close to a rear-seat passenger, and used for displaying images (e.g., video contents) for view by the rear-seat passengers.

The display device DD may be defined with a display area DA and a non-display area NDA. The display area may display an image and detect a user's input.

The display area DA may be parallel to a plane defined by a first directional axis DR1 and a second directional axis DR2.

A normal direction of the display area DA, i.e., a direction of a thickness of the display device DD may be defined by a third directional axis DR3. A front surface (or an upper surface) and a back surface (or a lower surface) may be distinguished by the third directional axis DR3. However, directions pointed by the first through the third directional axes DR1 through DR3 are merely a relative concept and may be converted into other directions. Hereinafter, the first through the third directions DR1 through DR3 are directions pointed by the first through the third directional axes DR1 through DR3, respectively, and described with the same figure references. A shape of the display area DA illustrated in FIG. 1A as an example may be modified without limitation as desired. The non-display area NDA is an area next (adjacent) to the display area DA that does not display an image. A bezel area of the display device DD may be defined by the non-display area NDA. The display area DA may be surrounded by the non-display area NDA. Yet, the shape of the display area DA and the non-display area NDA is not limited to the above configuration and may be modified. Referring to FIG. 1B, the display device DD may include an upper housing TH, a display module DPM, a circuit board PCB, and a lower housing BH. The upper housing TH may include a window member WP. The window member WP may allow penetration of incident light. Particularly, an image displayed in the display module DPM may penetrate through the window member WP to be viewed by a user. The window member WP may overlap with the display area DA.

The display module DPM may include a data driving unit DIC and a plurality of pads PD. In addition, the display module DPM may be defined with a display area DA and a non-display area NDA.

The display module DPM may be disposed below the upper housing TH. The upper housing TH may be provided to protect the display module DPM from an external impact, for example.

The data driving unit DIC may be electrically connected to the display area DA to transfer an electric signal.

The plurality of pads PD may contact and be electronically connected to the circuit board PCB. Accordingly, the display module DPM and the circuit board PCB may exchange an electric signal and power through the plurality of pads PD.

The circuit board PCB may include an input sensor driving unit TIC and a control driving unit CIC.

The input sensor driving unit TIC may be electronically connected to the display area DA to receive an electric signal.

The control driving unit CIC may control at least one of the data driving unit DIC and the input sensor driving unit TIC.

The lower housing BH may be disposed below the display module DPM. The lower housing BH may be provided to protect the display module DPM from an external impact, for example. Furthermore, the lower housing BH may house the display module DPM and the upper housing TH.

Furthermore, the display device DD may further include a power module (not shown), an acoustic module (not shown), and an optical module (not shown) that are not illustrated in FIG. 1B.

The power module (not shown) may provide power to the display module DPM, the acoustic module (not shown), and the optical module (not shown). The power module (not shown) may include a battery or a power supply unit.

The acoustic module (not shown) may detect user's sound and provide acoustic information to the user. The acoustic module (not shown) may include a mic and a speaker, for example.

The optical module (not shown) may film an external environment to film a photograph or a video, for example. The optical module (not shown) may include a camera and a wide-angle camera, for example.

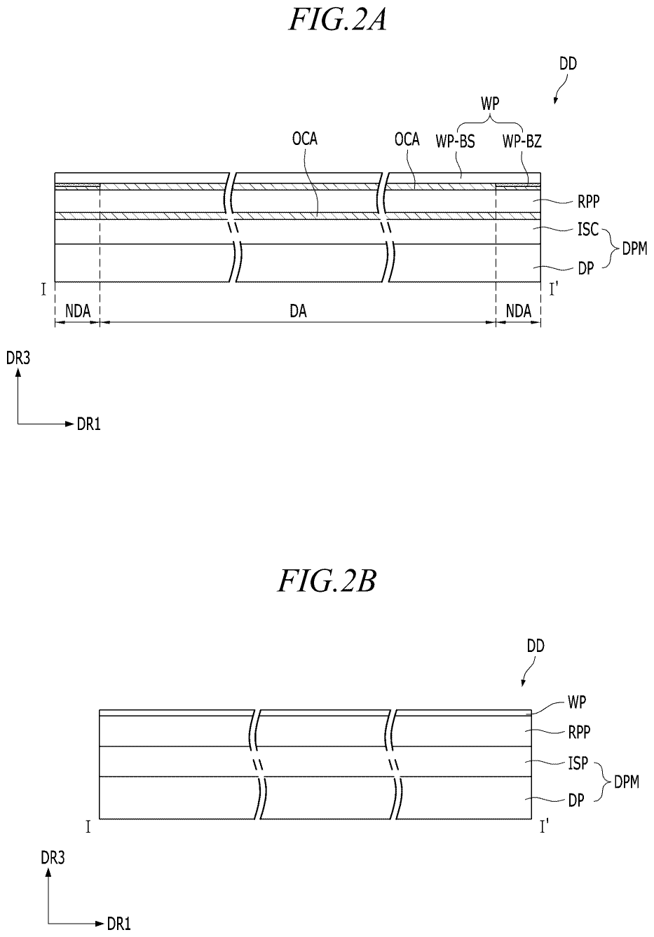

FIGS. 2A and 2B are exemplary illustrations of partial cross-sections taken along line I-I′ of FIG. 1.

FIGS. 2A and 2B illustrate partial cross-sections defined by the second directional axis DR2 and the third directional axis DR3. FIGS. 2A and 2B are simplified to describe laminated relationships among functional panels and/or functional members composing the display device DD.

As illustrated in FIG. 2A, the display device DD may include a display module DPM, a reflection protection member RPP, and a window member WP.

The display module DPM may include a display panel DP and an input sensor circuit ISC. In addition, the display panel DP and the input sensor circuit ISC may be directly disposed. When an element is “directly disposed on” another element, it shall be construed that there is no other adhesive layer/adhesive member interposed therebetween.

The display panel DP may be a light-emitting display panel. In an embodiment, the display panel DP may be an organic light-emitting display panel, a quantum dot light-emitting display panel, or a micro light-emitting display panel, for example. Hereinafter, the display panel DP is described as an organic light-emitting display panel. The input sensor circuit ISC is disposed on the display panel DP to obtain a coordination information of an external input. Particularly, at least one of a resistance film type input sensor, a capacitance type input sensor, an optical sensor, an electromagnetic resonance type input sensor, an ultrasonic type input sensor, and an infrared wave type input sensor may be used as the input sensor circuit ISC.

The reflection protection member RPP may be disposed on the display module DPM. The reflection protection member RPP may be coupled to the display module DPM by an optically clear adhesive member OCA. The reflection protection member RPP reduces a reflection rate of an external light incident from an upper side of the window member WP. The reflection protection member RPP in an embodiment of the disclosure may include a retarder, a polarizer, and a plurality of color filters.

The window member WP may be disposed on the reflection protection member RPP. The window member WP may be attached to the reflection protection member RPP by the optically clear adhesive member OCA.

The window member WP in an embodiment of the disclosure may include a base film WP-BS and a light-blocking pattern WP-BZ. The base film WP-BS may include a glass and/or a synthetic resin. The base film WP-BS is not limited to a single layer. The base film WP-BS may include two or more films coupled by an adhesive member.

The light-blocking pattern WP-BZ partially overlaps with the base film WP-BS. The light-blocking pattern WP-BZ may be disposed below the base film WP-BS to overlap with the non-display area NDA of the display device DD.

Hereinafter, the light blocking pattern WP-BZ and the base film WP-BS are not illustrated in FIG. 2B.

As illustrated in FIG. 2B, an adhesive member may be omitted in the display device DD, and the display panel DP, the input sensor circuit ISC, the reflection protection member RPP, and the window member WP may be consecutively laminated.

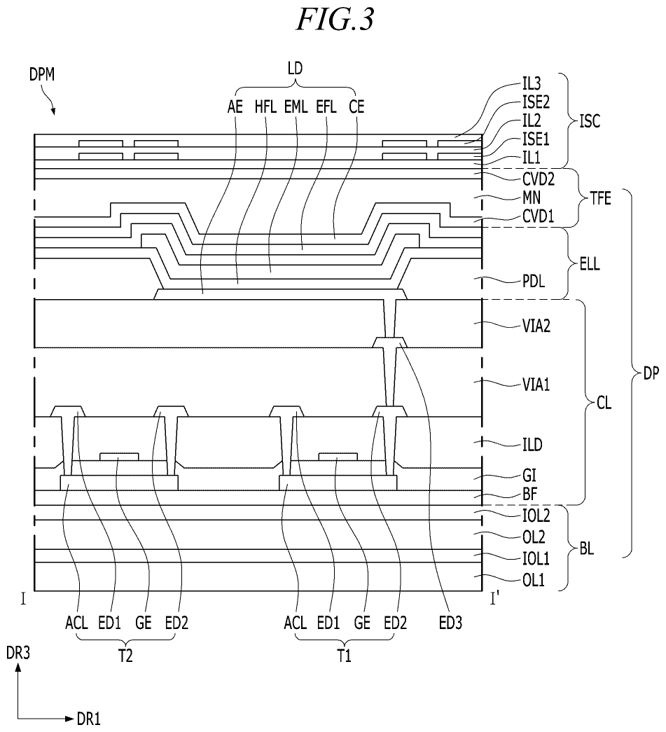

FIG. 3 is an exemplary illustration of an embodiment of a display module DPM according to the disclosure.

By referring to FIG. 3, the display module DPM may include a display panel DP and an input sensor circuit ISC. The display panel DP may include a base member BL, a circuit layer CL, a light-emitting component layer ELL, and an encapsulation layer TFE.

The base member BL may include a first organic layer OL1, a first inorganic layer IOL1, a second organic layer OL2, and a second inorganic layer IOL2. Furthermore, the base member BL may be a basis of the circuit layer CL. In other words, other elements of the circuit layer CL may be laminated on the base member BL.

The first organic layer OL1 may include an organic material. In an embodiment, polyimide may be included, for example.

The first inorganic layer IOL1 may be disposed on the first organic layer OL1. The first inorganic layer IOL1 may include an inorganic material.

The second organic layer OL2 may be disposed on the first inorganic layer IOL1. The second organic layer OL2 may include an organic material. In an embodiment, polyimide may be included, for example.

The second inorganic layer IOL2 may be disposed on the second organic layer OL2. The second inorganic layer IOL2 may include an inorganic material.

The plurality of organic layers OL1 and OL2 and the plurality of inorganic layers IOL1 and IOL2 may be alternately laminated. Through such configuration, it may become more difficult for an impurity flown from the bottom to penetrate through the base member BL. Accordingly, the circuit layer CL disposed above may be protected by the base member BL.

The circuit layer CL may include a buffer layer BF, a gate insulating layer GI, an inter-insulating layer ILD, a first circuit insulating layer VIA1, a second circuit insulating layer VIA2, and a plurality of transistors T1 and T2.

The plurality of transistors T1 and T2 may transfer an electrical signal. Furthermore, each of the plurality of transistors T1 and T2 may include an active unit ACL, a first electrode ED1, a control electrode GE, and a second electrode ED2.

The buffer layer BF may be disposed on the base member BL. The buffer layer BF may prevent an impurity flown from the bottom from moving above. Accordingly, an element disposed above the buffer layer BF may be protected.

The plurality of active units ACL composing each of the plurality of transistors T1 and T2 may be disposed on the buffer layer. Each of the plurality of active units ACL may include poly silicon or amorphous silicon. In addition plurality of active units ACL may include a metal oxide semiconductor. The plurality of active units ACL may include a channel area serving as a passage through which an electron or a hole may move, and a first ion-doped area, and a second ion-doped area disposed with the channel area therebetween.

The gate insulating layer may cover the buffer layer BF and a plurality of active units ACL. The gate insulating layer GI may include an organic and/or inorganic film. The gate insulating layer GI may include a plurality of inorganic thin films. The plurality of inorganic thin films may include a silicon nitride layer and a silicon oxide layer.

The plurality of control electrodes GE composing each of the plurality of transistors T1 and T2 may be disposed on the buffer layer BF. The plurality of control electrodes GE may overlap with the plurality of active units ACL. In addition, the plurality of control electrodes GE may include molybdenum (Mo).

The inter-insulating layer ILD may cover the gate insulating layer GI and the plurality of control electrodes GE. The inter-insulating layer ILD may include an organic film and/or an inorganic film. The inter-insulating layer ILD may include a plurality of inorganic films or organic films. The plurality of inorganic films may include a silicon nitride layer and silicon oxide layer.

The plurality of first electrodes ED1 and the plurality of second electrodes ED2 composing each of the plurality of transistors T1 and T2 may be disposed on the inter-insulating layer ILD. Each of the plurality of first electrodes ED1 and the plurality of second electrodes ED2 may be electrically connected to the plurality of active units ACL through the contact holes defined on the inter-insulating layer ILD. Furthermore, the first electrodes ED1 and the second electrodes ED2 may include a metal. In addition, the first electrodes ED1 and the second electrodes ED2 may have a multiple layer structure. Particularly, each of the first electrodes ED1 and the second electrodes ED2 may be successively laminated with Titanium Ti, Aluminum Al and Titanium Ti.

The first circuit insulating layer VIA1 may cover the inter-insulating layer ILD, the plurality of first electrodes ED1 and the plurality of second electrodes ED2. The first circuit insulating layer VIA1 may include an organic film and/or an inorganic film. The first circuit insulating layer VIA1 may provide a flat surface.

A third electrode ED3 may be disposed on the first circuit insulating layer VIAL. The third electrode ED3 may be electrically connected to the second electrode ED2 through the contact hole defined on the first circuit insulating layer VIA1. Furthermore, the third electrodes ED3 may include a metal. In addition, each of the third electrodes ED3 may have a multiple layer structure. Particularly, the third electrodes ED3 may be successively laminated with Titanium Ti, Aluminum Al and Titanium Ti.

The second circuit insulating layer VIA2 may cover the first circuit insulating layer VIA1 and the third electrode ED3. The second circuit insulating layer VIA2 may include an organic film and/or an inorganic film. The second circuit insulating layer VIA2 may provide a flat surface.

The number of the plurality of circuit insulating layers VIA1 and VIA2 is not limited to the above. The number of the plurality of circuit insulating layers VIA1 and VIA2 may increase as desired.

The light-emitting component layer ELL may include a pixel defining layer PDL and a light-emitting component (e.g., light-emitting diode) LD. The light-emitting component LD may emit light. Furthermore, the light-emitting component LD may include an anode electrode AE, a hole functional layer HFL, a light-emitting layer EML, an electron functional layer EFL, and a cathode electrode CE.

The pixel defining layer PDL may be disposed on a portion of the second circuit insulating layer VIA2. Accordingly, a remaining (the other) portion where the pixel defining layer PDL is not disposed may be defined with an opening area. In addition, the light-emitting component LD may be formed on the opening area.

The anode electrode AE may be disposed on a portion of the second circuit insulating layer VIA2, particularly the opening area. Furthermore, the anode electrode AE may be electrically connected to the third electrode ED3 through the contact hole defined on the second circuit insulating layer VIA2. Therefore, the anode electrode AE may receive an electric signal from the first transistor T1 and the second transistor T2.

In FIG. 3, the first transistor T1 and the second transistor T2 are illustrated, however the structures of the first transistor T1 and the second transistor T2 are not limited to what is illustrated in the figure. In FIG. 3, the first transistor T1 is illustrated to directly contact the anode electrode AE of the light-emitting component LD by the second electrode ED2 and the third electrode ED3, but this merely is a cross-sectional shape and is thus shown, and in fact, the first transistor T1 may be connected to the anode electrode AE of the light-emitting component LD through another transistor. However, the disclosure is not limited to this configuration, and in an embodiment of the disclosure, the first transistor T1 may directly contact the anode electrode AE of the light-emitting component LD by the second electrode ED2 and the third electrode ED3.

The hole functional layer HFL may be disposed on the anode electrode AE. The hole functional layer HFL may support transfer of a hole generated from the anode electrode AE. In an embodiment, the hole functional layer HFL may more easily receive a hole injected from the anode electrode AE, and the hole may be more easily transferred, for example. The hole functional layer HFL may have a multiple layer structure. In an embodiment, the hole functional layer HFL may have a structure of further including a hole injection layer (not shown) and a hole transfer layer (not shown), for example.

The light-emitting layer EML may be disposed on the hole functional layer HFL. The light-emitting layer EML may emit light. The light-emitting layer EML may include an organic light-emitting material or a quantum dot. Furthermore, the light-emitting component LD may be an OLED or a quantum dot light-emitting diode.

The electron functional layer EFL may be disposed on the light-emitting layer EML. The electron functional layer EFL may support transfer of an electron generated from the cathode electrode CE. In an embodiment, the electron functional layer EFL may more easily receive an electron injected from the cathode electrode CE, and the electron may be more easily transferred, for example. The electron functional layer EFL may have a multiple layer structure. In an embodiment, the electron functional layer EFL may have a structure of further including an electron injection layer (not shown) and an electron transfer layer (not shown), for example.

The cathode electrode CE may be disposed on the electron functional layer EFL. The cathode electrode CE may have relatively low resistance so that electron current may easily flow.

The encapsulation layer TFE may seal off the light-emitting component LD to protect the light-emitting component LD from external oxygen or moisture. The encapsulation layer TFE may include a first encapsulation inorganic layer CVD1, an encapsulation organic layer MN, and a second encapsulation inorganic layer CVD2.

In FIG. 3, the encapsulation layer TFE is illustrated, in an embodiment, to include two encapsulation inorganic layers CVD1 and CVD2 and one encapsulation organic layer MN, but the disclosure is not limited to this example. In an embodiment, the encapsulation layer TFE may include three encapsulation inorganic layers and two encapsulation organic layers, and in this case, the encapsulation inorganic layers and the encapsulation organic layers may be alternately laminated, for example.

The input sensor circuit ISC may generate an input sensor signal from an external input. The input sensor circuit ISC may include a first inorganic insulating layer IL1, a first input sensor electrode ISE1, and a second inorganic insulating layer IL2, a second input sensor electrode ISE2, and a third inorganic insulating layer IL3.

The first inorganic insulating layer IL1 may be disposed on the encapsulation layer TFE. The first inorganic insulating layer IL1 may have a single layer structure or a multiple layer structure and include an inorganic material or a composite material. An inorganic material may include at least one of aluminum oxide, titanium oxide, silicon oxide, silicon oxynitride, zirconium oxide, and hafnium oxide. In another embodiment, the first inorganic insulating layer IL1 may be replaced with an organic insulating layer. Furthermore, the first inorganic insulating layer IL1 may be omitted.

The first input sensor electrode ISE1 may be disposed on the first inorganic insulating layer ILL. The first input sensor electrode ISE1 may have a single layer structure or a laminated multiple layer structure. The electrode of a single layer structure may include a metal layer or a transparent electrode. The metal layer may include a molybdenum, silver, titanium, copper, aluminum, and any alloys thereof. The transparent electrode may include a transparent conductive oxide, such as indium tin oxide (“ITO”), indium zinc oxide (“IZO”), zinc oxide (ZnO), or indium tin zinc oxide (“ITZO”). Another transparent electrode may include a conductive polymer, such as poly(3,4-ethylenedioxythiophene) (“PEDOT”), a metallic nanowire, or graphene. Furthermore, the multiple layer structure may be successively laminated with Titanium (Ti), Aluminum (Al), and Titanium (Ti).

The second inorganic insulating layer IL2 may be disposed on the first input sensor electrode ISEL. The predetermined configuration of the second inorganic insulating layer IL2 may be the same as that of the first inorganic insulating layer ILL.

The second input sensor electrode ISE2 may be disposed on the second inorganic insulating layer IL2. The predetermined configuration of the second input sensor electrode ISE2 may be the same as that of the first input sensor electrode ISEL.

A capacitor may be formed between the first input sensor electrode ISE1 and the second input sensor electrode ISE2. Furthermore, the capacitor may be affected by an external input. Change in microcurrent may be caused by the capacitor to generate an electron sensor signal so that a coordinate information may be obtained through the input sensor signal.

The third insulating layer IL3 may be disposed on the second input sensor electrode ISE2. The predetermined configuration of the third inorganic insulating layer IL3 may be the same as that of the first inorganic insulating layer IL1.

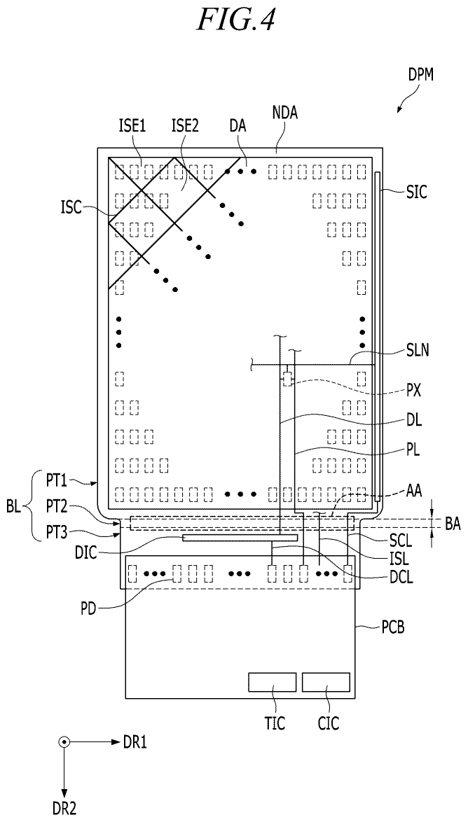

FIG. 4 is an exemplary plan view of an embodiment of a display module according to the disclosure. The display module DPM may include a plurality of pixels PX, a data driving unit DIC, a scan driving unit SIC, an input sensor circuit ISC, a plurality of pads PD, a circuit board PCB, an input sensor driving unit TIC, a control driving unit CIC, a plurality of data driving control lines DCL, a plurality of data lines DL, a plurality of scan driving unit control lines (also referred to as scan driving control lines) SCL, a plurality of scan lines SLN, a plurality of power lines PL, and a plurality of input sensor lines ISL.

Referring to FIG. 4, the base member BL may be defined with a first area PT1, a second area PT2, and a third area PT3. Furthermore, the first area PT1 may include a display area DA and a non-display area NDA.

In addition, an area surrounding the display area DA in the first area PT1 may be defined as the non-display area NDA. Furthermore, the light-emitting component LD disposed on the base member BL may overlap with the display area DA. In addition, the plurality of input sensor electrodes ISE1 and ISE2 may be disposed on the display area DA. The display area DA and the non-display area NDA of the base member BL may correspond to the display area DA and the non-display area NDA of the display device DD illustrated in FIG. 1.

The second area PT2 may be defined as an area extending from the first area PT1. The second area PT2 may be bent. Accordingly, a ratio of the display area DA may be increased in the display module DPM. As the second area PT2 is bent, the second area PT2 may be referred as the bending area BA. The configuration where the second area PT2 is bent is more specifically described in another figure.

The third area PT3 may be defined as an area extending from the second area PT2. The data driving unit DIC may be disposed in the third area PT3. Furthermore, the plurality of pads PD may be disposed in the third area PT3 to be electrically connected to the circuit board PCB.

In FIG. 4, the plurality of data driving control lines DCL, the plurality of data lines DL, the plurality of scan driving unit control lines SCL, the plurality of scan lines SLN, the plurality of power lines PL, and the plurality of input sensor lines ISL are illustrated as one, respectively, this is simplified merely for explanation, and they may be disposed in a plurality. In addition, in an embodiment of the disclosure, a line which is not illustrated in FIG. 4 may be further included. In an embodiment, a light-emitting control line may be further included, for example.

The plurality of pixels PX may be disposed in a plurality inside the display area DA. Furthermore, the plurality of pixels PX may receive power and an electric signal to emit light. The light emitted by the plurality of pixels PX by the electric signal may be controlled to control an image displayed in the display area DA.

The input sensor circuit ISC may generate an input sensor signal from an external input.

The data driving unit DIC may be electrically connected to the plurality of pixels PX in the display area DA to provide a data signal to the plurality of pixels PX.

The scan driving unit SIC may be electrically connected to the plurality of pixels PX in the display area DA to provide a scan signal to the plurality of pixels PX.

The input sensor driving unit TIC and the control driving unit CIC may be disposed (e.g., mounted) on the circuit board PCB to receive an input sensor signal from the plurality of pads PD.

The input sensor driving unit TIC may process the received input sensor signal by the plurality of pads PD.

The control driving unit CIC may be a circuit configured to control at least one of the data driving unit DIC and the input sensor driving unit TIC.

The plurality of data driving control lines DCL may receive a data driving control signal from the plurality of pads PD to transfer it to the data driving unit DIC.

The plurality of data lines DL may receive a data signal from the data driving unit DIC to transfer it to the plurality of pixels PX.

The plurality of scan driving unit control lines SCL may receive a scan driving unit control signal from the plurality of pads PD to transfer it to the scan driving unit SIC.

The plurality of scan lines SLN may receive a scan signal from the scan driving unit SIC to transfer it to the plurality of pixels PX.

The plurality of power lines PL may receive power from the plurality of pads PD to transfer it to the plurality of pixels PX. In addition, the power may be direct-current (“DC”) power.

The plurality of input sensor lines ISL may receive an input sensor signal generated from the input sensor circuit ISC to transfer it to the plurality of pads PD.

Through the above configuration, the input sensor signal generated from the input sensor circuit ISC disposed in the first area PT1 may be transferred to the plurality of pads PD in the third area PT3, the data signal generated from the data signal generated from the data driving unit DIC disposed in the third area PT3 may be transferred to the plurality of pixels PX disposed in the first area PT1, and the scan driving unit control signal may be transferred from the plurality of pads PD disposed in the third area PT3 to the scan driving unit SIC disposed in the first area PT1.

Accordingly, a signal may be transferred through the plurality of input sensor lines ISL, the plurality of data lines DL, and the plurality of scan driving unit control lines SCL disposed in the second area PT2. Therefore, electromagnetic interference may be generated in the second area PT2. Nonetheless, the electromagnetic interference generated in the second area PT2 may be blocked in an embodiment of the disclosure. A configuration of blocking the electromagnetic interference is more specifically described through another figure later.

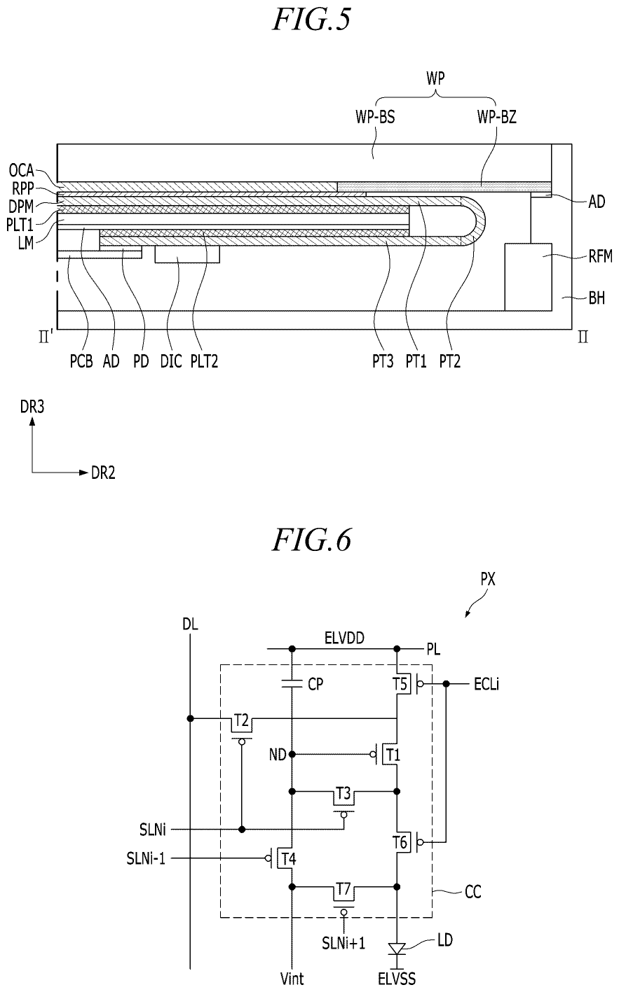

FIG. 5 is an exemplary illustration of a partial cross-section taken along line II-II′ of FIG. 1. Referring to FIG. 5, the display device DD may further include a communication module RFM, a first plate PLT1, a second plate PLT2, a rear module LM, and a plurality of adhesive agents AD.

The communication module RFM may receive or transmit an electromagnetic wave. When the electromagnetic wave interference occurs, the communication module RFM may receive or transmit incorrect information due to the electromagnetic interference. In other words, the electromagnetic interference may serve as a noise in the communication module RFM. In the disclosure, the electromagnetic interference generated in the second area PT2 may be blocked, and the communication module RFM may be disposed in front of the second area PT2. A configuration of blocking the electromagnetic interference is more specifically described through another figure later.

The first plate PLT1 may be interposed between the first area PT1 and the third area PT3. The first plate PLT1 may overlap with a portion of the first area PT1. The second plate PLT2 may be interposed between the first area PT1 and the third area PT3. The second plate PLT2 may overlap with a portion of the third area PT3. The rear module LM may be interposed between the first plate PLT1 and the second plate PLT2. Furthermore, the rear module LM may be attached to the second plate PLT2.

The plurality of adhesive agents AD may attach the rear module LM and the second plate PLT2. Furthermore, the plurality of adhesive agents AD may attach the upper housing (not shown) and the lower housing BH.

FIG. 6 is an illustration of an embodiment of an equivalent circuit of a pixel according to the disclosure. FIG. 6 is an exemplary illustration of a pixel PX connected to an i-th scan line SLNi (i is a natural number greater than 1) and an i-th light-emission control line ECLi. The pixel PX may include a light-emitting component LD and a pixel circuit CC.

In the disclosure, an organic light-emitting diode (“OLED”) is described as a light-emitting component LD.

The pixel circuit CC may include a plurality of transistors T1 through T7 and a capacitor CP. The pixel circuit CC may respond to the data signal to control current flowing through the light-emitting component LD.

The light-emitting component LD may emit light with a determined luminance corresponding to the amount of current provided from the pixel circuit CC. To that end, a level of a first power ELVDD may be set higher than a level of a second power ELVSS.

Each of the plurality of transistors T1 to T7 may include an input electrode (or a source electrode), an output electrode (or a drain electrode), and a control electrode (or a gate electrode). In the disclosure, for convenience, one of the input electrode and the output electrode may be also referred to as a first electrode, and a remaining (the other) one may be also referred to as a second electrode.

The first electrode of the first transistor T1 is connected to the first power ELVDD via the fifth transistor T5, and the second electrode is connected to the anode electrode of the light-emitting component LD via the sixth transistor T6. The first transistor T1 may be also referred to as a driving transistor in this specification.

The first transistor T1 controls the amount of current flowing through the light-emitting component LD in response to a voltage applied to the control electrode.

The second transistor T2 is connected between the data line DL and the first electrode of the first transistor T1. In addition, the control electrode of the second transistor T2 is connected to the i-th scan line SLi. When the i-th scan signal Si is provided to the i-th scan line SLi, the second transistor T2 is turned on to electrically connect the data line DL and the first electrode of the first transistor T1.

The third transistor T3 is connected between the second electrode of the first transistor T1 and the control electrode. The control electrode of the third transistor T3 is connected to the i-th scan line SLi. When the i-th scan signal Si is provided to the i-th scan line SLi, the third transistor T3 is turned on to electrically connect the second electrode of the first transistor T1 and the control electrode. Accordingly, when the third transistor T3 is turned on, the first transistor T1 is connected in the form of a diode.

The fourth transistor T4 is connected between the node ND and an initialization power generation unit (not shown). In addition, the control electrode of the fourth transistor T4 is connected to the (i−1)-th scan line SLi−1. When the (i−1)-th scan signal Si−1 is provided to the (i−1)-th scan line SLi−1, the fourth transistor T4 is turned on to provide an initialization voltage Vint to the node ND.

The fifth transistor T5 is connected between a power line PL and the first electrode of the first transistor T1. The control electrode of the fifth transistor T5 is connected to the i-th light-emission control line ECLi.

The sixth transistor T6 is connected between the second electrode of the first transistor T1 and the anode electrode of the light-emitting component LD. In addition, the control electrode of the sixth transistor T6 is connected to the i-th light-emission control line ECLi.

The seventh transistor T7 is connected between the initialization power generation unit (not shown) and the anode electrode of the light-emitting component LD. In addition, the control electrode of the seventh transistor T7 is connected to the (i+1)-th scan line SLi+1. When the (i+1)-th scan signal Si+1 is provided to the (i+1)-th scan line SLi+1, such seventh transistor T7 is turned on to provide the initialization voltage Vint to the anode electrode of the light-emitting component LD. The seventh transistor T7 may improve the black expression capability of the pixel PX. Specifically, when the seventh transistor T7 is turned on, a parasitic capacitor (not shown) of the light-emitting component LD is discharged. Then, when the black luminance is implemented, the light-emitting component LD does not emit light due to the leakage current from the first transistor T1, and accordingly, the black expression capability may be improved.

Additionally, in FIG. 6, the control electrode of the seventh transistor T7 is shown to be connected to the (i+1)-th scan line SLi+1, but the disclosure is not limited to this configuration. In another embodiment of the disclosure, the control electrode of the seventh transistor T7 may be connected to the i-th scan line SL1 or the (i−1)-th scan line SLi−1. Illustration of FIG. 4 is based on p-channel metal-oxide semiconductor (“PMOS”), but the disclosure is not limited to this configuration. In another embodiment of the disclosure, the pixel PX may consist of n-channel metal-oxide semiconductor (“NMOS”). In another embodiment of the disclosure, the pixel PX may consist of a combination of NMOS and PMOS.

The capacitor CP is interposed between the power line PL and the node ND. The capacitor CP stores a voltage corresponding to the data signal. When the fifth transistor T5 and the sixth transistor T6 are turned on, the amount of current flowing through the first transistor T1 may be determined according to the voltage stored in the capacitor CP.

In the disclosure, the structure of the pixel PX is not limited to what is illustrated in FIG. 6. In another embodiment of the disclosure, the pixel PX may be implemented in various forms configured for the light-emitting component LD to emit light.

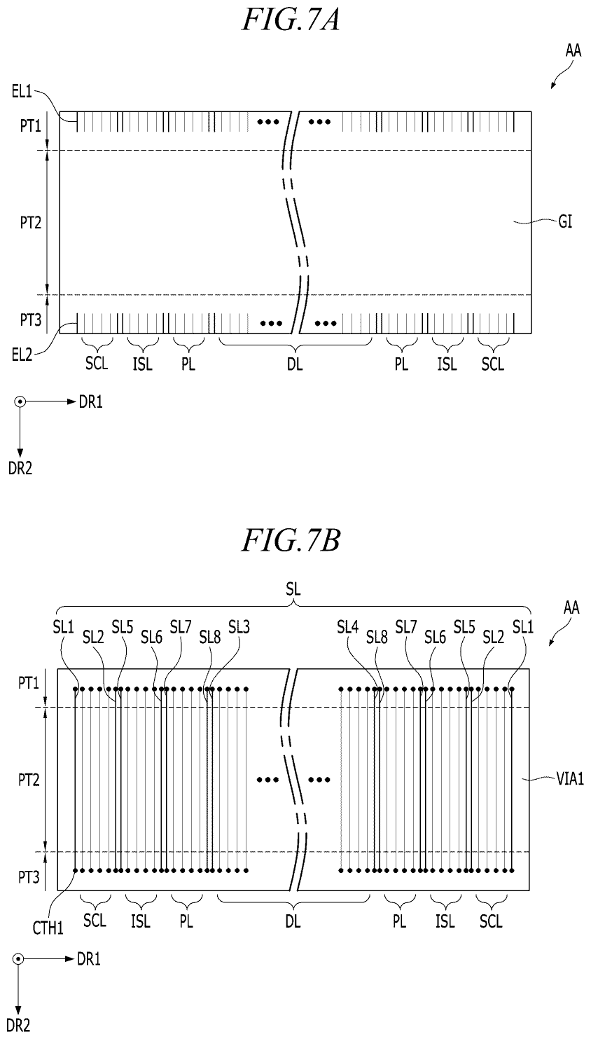

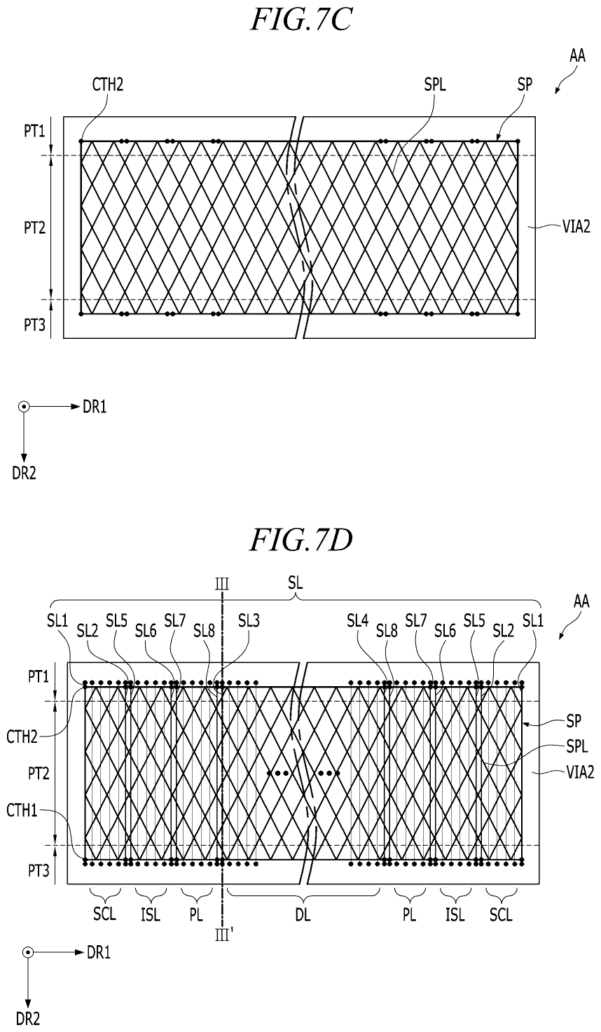

FIG. 7A is an exemplary illustration of an upper surface of a gate insulating layer GI in an area corresponding to section AA shown in FIG. 5. FIG. 7B is an exemplary illustration of an upper surface of a first circuit insulating layer VIA1 in an area corresponding to section AA shown in FIG. 5. FIG. 7C is an exemplary illustration of an upper surface of a second circuit insulating layer VIA2 in an area corresponding to section AA shown in FIG. 5. FIG. 7D is an exemplary illustration of a plurality of shielding lines SL and a shielding pattern SP on the same plane in an area corresponding to section AA shown in FIG. 5.

Referring to FIG. 7A, the plurality of scan driving unit control lines SCL, the plurality of input sensor lines ISL, the plurality of power lines PL, the plurality of data lines DL, the plurality of first lines EL1, and the plurality of second lines EL2 may be disposed on the upper surface of the gate insulating layer GI.

A portion of the upper plane of the gate insulating layer GI corresponding to the first area PT1 is defined as a first plane, and the first plane may be parallel to the first area PT1. In addition, a portion of the upper plane of the gate insulating layer GI corresponding to the third area PT3 is defined as a second plane, and the second plane may be parallel to the third area PT3. Furthermore, the upper plane of the gate insulating layer GI may be defined as a plane that is the most distant from the base member BL among the planes composing the gate insulating layer GI.

The plurality of first lines EL1 may be disposed on the first plane and overlap with the first area PT1. The plurality of second lines EL2 may be disposed on the second plane and overlap with the third area PT3. Furthermore, the plurality of second lines EL2 may correspond to the plurality of first lines EL1, respectively.

Referring to FIG. 7B, the plurality of scan driving unit control lines SCL, the plurality of input sensor lines ISL, the plurality of power lines PL, the plurality of data lines DL, and the plurality of shieling lines SL may be disposed on the first circuit insulating layer VIAL. Furthermore, the first circuit insulating layer VIA1 may be defined with a plurality of first contact holes CTH1.

An upper surface of the first circuit insulating layer VIA1 may be defined as a third plane, and the third plane may correspond to the second area PT2. Furthermore, the upper surface of the first circuit insulating layer VIA1 may be defined as a plane that is most distant from the base member BL among the planes composing the first circuit insulating layer VIAL.

The plurality of shielding lines SL may be disposed on the first circuit insulating layer VIA1 and overlap with the second area PT2. When an element is described to “overlap with” another element in the disclosure, the element is disposed in a normal direction of a surface of a remaining (the other) element, which is not limited to being disposed above or below a plane. Furthermore, the plurality of shielding lines SL may include a first shielding line SL1, a second shielding line SL2, a third shielding line SL3, a fourth shielding line SL4, a fifth shielding line SL5, a sixth shielding line SL6, a seventh shielding line SL7, and an eighth shielding line SL8. The first shielding line SL1 may be a portion of the plurality of shielding lines SL.

The second shielding line SL2 may be disposed parallel to the first shielding line SLi with the plurality of scan driving unit control lines SCL therebetween. In other words, the plurality of scan driving unit control lines SCL may be interposed between the first shielding line SL1 and the second shielding line SL2.

The third shielding line SL3 may be spaced apart from the second shielding line SL2.

The fourth shielding line SL4 may be disposed parallel to the third shielding line SL3 with the plurality of data lines DL therebetween. In other words, the plurality of data lines DL may be interposed between the third shielding line SL3, and the fourth shielding line SL4.

The fifth shielding line SL5 may be spaced apart from the fourth shielding line SL4.

The sixth shielding line SL6 may be disposed parallel to the fifth shielding line SL5 with the plurality of input sensor lines ISL therebetween. In other words, the plurality of input sensor lines ISL may be interposed between the fifth shielding line SL5, and the sixth shielding line SL6.

The seventh shielding line SL7 may be spaced apart from the sixth shielding line SL6.

The eighth shielding line SL8 may be disposed parallel to the seventh shielding line with the plurality of power lines PL therebetween. In other words, the plurality of power lines PL may be interposed between the seventh shielding line SL7, and the eighth shielding line SL8.

The plurality of first contact holes CTH1 may be disposed on opposite sides of the plurality of scan driving unit control lines SCL, the plurality of input sensor lines ISL, the plurality of power lines PL, the plurality of data lines DL, and the plurality of shielding lines SL.

The upper side of the first circuit insulating layer VIA1, i.e., the third plane, may be a neutral plane. In other words, when the display module DPM is bent, the plane may not be applied with stress. Accordingly, when the second area PT2 is bent, the plurality of scan driving unit control lines SCL, the plurality of input sensor lines ISL, the plurality of power lines PL, the plurality of data lines DL, and the plurality of shielding lines SL that are disposed on the upper surface of the first circuit insulating layer VIA1 and overlap with the second area PT2 may not be applied with stress so that they may remain undamaged.

Subsequently, referring to FIGS. 7A and 7B, the plurality of scan driving unit control lines SCL, the plurality of input sensor lines ISL, the plurality of power lines PL, the plurality of data lines DL, the plurality of first lines EL1, the plurality of second lines EL2 and the shielding line SL are more specifically described.

The plurality of scan driving unit control lines SCL in FIG. 7A may be electrically connected to one another through the plurality of scan driving unit control lines SCL and the plurality of first contact holes CTH1 in FIG. 7B. Accordingly, the scan driving unit control signal may be transferred from the third area PT3 to the first area PT1.

The plurality of input sensor lines ISL in FIG. 7A may be electrically connected to one another through the plurality of input sensor lines ISL and the plurality of first contact holes CTH1 in FIG. 7B. Accordingly, the input sensor signal may be transferred from the first area PT1 to the third area PT3.

The plurality of power lines PL in FIG. 7A may be electrically connected to one another through the plurality of power lines PL and the plurality of first contact holes CTH1 in FIG. 7B. Accordingly, the power may be transferred from the third area PT3 to the first area PT1.

The plurality of data lines DL in FIG. 7A may be electrically connected to one another through the plurality of data lines DL and the plurality of first contact holes CTH1 in FIG. 7B. Accordingly, the data signal may be transferred from the third area PT3 to the first area PT1.

The plurality of first lines EL1 and the plurality of second lines EL2 in FIG. 7AW may be electrically connected to one another through the plurality of first contact holes CTH1 and the plurality of shielding lines SL in FIG. 7B. Particularly, the plurality of shielding lines SL may extend in a direction of intersection with the first plane in the first area PT1 through the plurality of second contact holes CTH2 to contact the plurality of first lines EL1. Furthermore, the plurality of shielding lines SL may extend in a direction of intersection with the second plane in the third area PT3 through the plurality of second contact holes CTH2 to contact the plurality of second lines EL2.

Referring to FIG. 7C, a shielding pattern SP may be disposed on the second circuit insulating layer VIA2. Furthermore, the shielding pattern SP may include a plurality of shielding pattern lines SPL. In addition, the second circuit insulating layer VIA2 may be defined with a plurality of second contact holes CTH2.

An upper surface of the second circuit insulating layer VIA2 may be defined as a fourth plane, and the fourth plane may correspond to the second area PT2. The upper surface of the second circuit insulating layer VIA2 may be defined as a plane that is most distant from the base member BL among the planes composing the second circuit insulating layer VIA2.

The shielding pattern SP may be formed by arranging and connecting the plurality of shielding pattern lines SPL. In addition, each of the plurality of shielding pattern lines SPL may have at least a portion extending in a direction of intersection with the plurality of shielding lines SL. Therefore, the shielding pattern SP may substantially have a mesh shape.

Furthermore, the shielding pattern SP in the mesh shape may be disposed on the scan driving unit control lines SCL, the plurality of input sensor lines ISL, the plurality of power lines PL, and the plurality of data lines DL. Therefore, the shielding pattern SP may block electromagnetic interference generated from the plurality of scan driving unit control lines SCL, the plurality of input sensor lines ISL, the plurality of power lines PL, and the plurality of data lines DL.

The plurality of second contact holes CTH2 may be disposed on where the shielding line SL and the shielding pattern SP overlap. Accordingly, the shielding line SL and the shielding pattern SP may be electrically connected to each other through the plurality of second contact holes CTH2. Therefore, when power is applied to the shielding line SL, power may also be applied to the shielding pattern SP. As the result, power may be applied to the shielding pattern SP so that the shielding pattern SP may more efficiently block electromagnetic interference.

In addition, a portion of the plurality of second contact holes CTH2 may overlap with the first area PT1 and the rest may overlap with the third area PT3. Accordingly, the shielding line SL and the shielding pattern SP may overlap in the first area PT1 and the third area PT3. Particularly, the shielding pattern SP may extend in a direction of intersection with the third plane in the first area PT1 to contact the plurality of shielding lines SL through the plurality of second contact holes CTH2. In addition, the shielding pattern SP may extend in a direction of intersection with the third plane in the third area PT3 to contact the plurality of shielding lines SL through the plurality of second contact holes CTH2.

The upper surface of the second circuit insulating layer VIA2, i.e., the fourth plane, may not be a neutral plane. In other words, when the display module DPM is bent, stress may be applied. In an embodiment, tensile stress may be applied, for example. Accordingly, when the second area PT2 is bent, the shielding pattern SP disposed on the upper surface of the second circuit insulating layer VIA2 may be damaged.

However, as the shielding pattern SP has a mesh shape, even when a portion of the shielding pattern SP is damaged, power may be applied to the shielding pattern through an undamaged portion. Accordingly, even in the case where a portion of the shielding pattern SP is damaged, electromagnetic interference may be blocked.

In addition, the shielding pattern SP may contact the plurality of shielding lines SL in the first area PT1 and the third area PT3. Even when the second area PT2 is bent, the plurality of shielding lines SL may remain undamaged. Accordingly, even when a middle area of the shielding pattern SP is cut off, voltage may be applied in the first area PT1 and the third area PT3. Accordingly, there is merely a difficulty in blocking electromagnetic interference in a relatively small area created as the shielding pattern SP is cut off, and the effect of blocking electromagnetic interference may be maintained in majority of the area.

Referring to FIG. 7D, the plurality of scan driving unit control lines SCL, the plurality of input sensor lines ISL, the plurality of power lines PL, the plurality of data lines DL, the plurality of shielding lines SL, and the shielding pattern SP may be illustrated at the same time.

Through FIG. 7D, it may be confirmed that the shielding pattern SP overlaps with the plurality of scan driving unit control lines SCL, the plurality of input sensor lines ISL, the plurality of power lines PL, and the plurality of data lines DL.

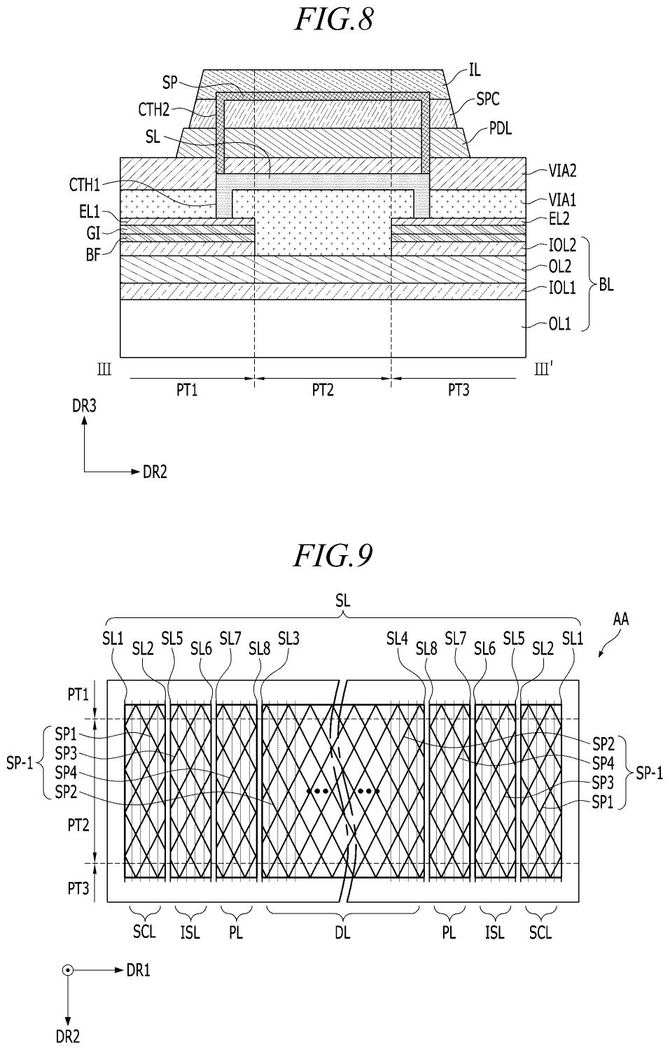

FIG. 8 is an exemplary illustration of a partial cross-section taken along line III-III′ of FIG. 7D.

Referring to FIG. 8, a portion corresponding to the second area PT2 in the display module DPM may include a first organic layer OL1, a first inorganic layer IOL1, a second organic layer OL2, a second inorganic layer IOL2, a buffer layer BF, a gate insulating layer GI, a plurality of first electrodes ED1, a plurality of second electrodes ED2, a first circuit insulating layer VIA1, a shielding line SL, a second circuit insulating layer VIA2, a pixel defining layer PDL, a spacer SPC, a shielding pattern SP, and an inorganic insulating layer IL.

In FIG. 8, the same configuration as in FIG. 3 may be included. Furthermore, the same configuration may be formed through the same process in the preparation method for a display module DPM. The second inorganic layer IOL2 may not be disposed in the second area PT2 in the base member BL.

The plurality of first lines EL1 may be disposed in an area defined by the first plane within the upper surface of the gate insulating layer GI. In addition, the plurality of first lines EL1 may be formed through the same process as for the control electrode in FIG. 3. In an embodiment, the plurality of first lines may be manufactured through the physical vapor deposition (“PVD”) process, for example. Furthermore, the PVD process may be a sputtering process. Accordingly, the plurality of first lines EL1 and the plurality of control electrodes GE may include or consist of the same material as each other. Therefore, the plurality of first lines EL1 may include molybdenum (Mo).

The plurality of second lines EL2 may be disposed in an area defined by the second plane within the upper surface of the gate insulating layer GI. Furthermore, the plurality of second lines EL2 may be manufactured through the same process for the plurality of control electrodes GE in FIG. 3. In an embodiment, the plurality of second lines EL2 may be manufactured through the PVD process, for example. In addition, the PVD process may be a sputtering process. Accordingly, the plurality of second lines EL2 and the plurality of control electrodes GE may include or consist of the same material as each other. Therefore, the plurality of second lines EL2 may include molybdenum (Mo).

The first circuit insulating layer VIA1 may cover the plurality of first lines EL1 and the plurality of second lines EL2 and disposed on the first area PT1, the second area PT2, and the third area PT3. The first circuit insulating layer VIA1 may be manufactured through a photolithography process. In addition, an upper surface of the first circuit insulating layer VIA1 may be defined as a third plane, and the third plane may correspond to the second area PT2.

The first circuit insulating layer VIA1 may be defined with a plurality of first contact holes CTH1. The plurality of first contact holes CTH1 may be manufactured through a dry etching process, and the first circuit insulating layer VIA1 may be formed by etching. The plurality of first contact holes CTH1 may overlap with the first area PT1 and the third area PT3.

The plurality of shielding lines SL may contact the first line EL1 and the second line EL2 through the plurality of first contact holes CTH1 disposed in the first area PT1 and the plurality of first contact holes CTH1 disposed in the third area PT3. Therefore, the plurality of first lines EL1 and the plurality of second lines EL2 may be electrically connected. In addition, the plurality of shielding lines SL may be manufactured through the same process as for the third electrode ED3 in FIG. 3. In an embodiment, the plurality of shielding lines SL may be manufactured through a PVD process, for example. In addition, the PVD process may be a sputtering process. Therefore, the plurality of shielding lines SL may have the same multiple layer structure as the third electrode ED3. Particularly, each of the plurality of shielding lines SL may be successively laminated by titanium (Ti), aluminum (Al), and titanium (Ti). In addition, the multiple layer structure may have a thickness of 5000 angstroms to 7000 angstroms.

The second circuit insulating layer VIA may cover the plurality of shielding lines SL and disposed on the first area PT1, the second area PT2, and the third area PT3. The second circuit insulating layer VIA2 may be manufactured through a photolithography process. The pixel defining layer PDL may be disposed on a portion of the first area PT1, the second area PT2, and the third area PT3. The pixel defining layer PDL may be manufactured through a photolithography process. Therefore, the pixel defining layer PDL may not be disposed on some portion.

The spacer SPC may be disposed on a portion of the first area PT1, the second area PT2 and the third area PT3. The spacer SPC may be manufactured through a photolithography process. Therefore, the spacer SPC may not be disposed on some portion. In addition, an upper surface of the spacer SPC may be defined as a fourth plane. The fourth plane may correspond to the second area PT2. In addition, the upper surface of the spacer SPC may be defined as a plane that is the most distant from the base member BL among the planes composing the spacer SPC.

In addition, the second circuit insulating layer VIA2, the pixel defining layer PDL, and the spacer SPC may be defined with a plurality of second contact holes CTH2. The plurality of second contact holes CTH2 may be manufactured through a dry etching process, and the second circuit insulating layer VIA2, the pixel defining layer PDL, and the spacer SPC may be formed by etching. The plurality of second contact holes CTH2 may overlap with the first area PT1 and the third area PT3.

The shielding pattern SP may contact the plurality of shielding lines SL through the plurality of second contact holes CTH2 disposed in the first area PT1 and the plurality of second contact holes CTH2 disposed in the third area PT3. Therefore, even in the case where an area in the middle of the shielding pattern SP is cut off, voltage may be applied to the first area PT1 and the third area PT3. Accordingly, there is merely a difficulty in blocking electromagnetic interference in a relatively small area created as the shielding pattern SP is cut off, and the effect of blocking electromagnetic interference may be maintained in majority of the area

Furthermore, the shielding pattern SP may be manufactured through the same process as for the first input sensor electrode ISE1 or the second input sensor electrode ISE2 in FIG. 3. In an embodiment, the shielding pattern SP may be manufactured through a PVD process. In addition, the PVD process may be a sputtering process, for example. Therefore, the shielding pattern SP may have a single layer structure similarly to the first input sensor electrode ISE1 and the second input sensor electrode ISE2, or a laminated multiple layer structure. An electrode of a single layer structure may include a metal layer or a transparent electrode. The metal layer may include molybdenum, silver, titanium, copper, aluminum, and any alloys thereof. A transparent electrode may include a transparent, conductive oxide, such as indium tin oxide (“ITO”), indium zinc oxide (“IZO”), zinc oxide (ZnO), and indium tin zinc oxide (“ITZO”). Other transparent electrode may include, e.g., a conductive polymer, such as poly(3,4-ethylenedioxythiophene) (“PEDOT”), a metallic nanowire, or graphene. In addition, the multiple layer structure may be formed by successively laminating titanium (Ti), aluminum (Al), and titanium (Ti). Furthermore, the multiple layer structure may have a thickness of 2500 angstroms to 3500 angstroms.

The inorganic insulating layer IL may cover the shielding pattern SP and disposed on a portion of the first area PT1, the second area PT2, and the third area PT3. In addition, the inorganic insulating layer IL may be manufactured through the same process as for the second inorganic insulating layer IL2 or the third inorganic insulating layer IL3 in FIG. 3. In an embodiment, the inorganic insulating layer IL may be manufactured through a chemical vapor deposition (“CVD”) process. In addition, the CVD process may be a plasma enhanced chemical vapor deposition (“PECVD”) process, for example.

Subsequently, another embodiment of the disclosure is more specifically described by referring to the figure.

FIG. 9 is an exemplary illustration of the plurality of shielding lines SL and the shielding pattern SP-1 on the same plane in an area corresponding to section AA shown in FIG. 5.

Referring to FIG. 9, the shielding pattern SP-1 may include a first shielding pattern SP1, a second shielding pattern SP2, a third shielding pattern SP3, and a fourth shielding pattern SP4.

The first shielding pattern SP1 may overlap with the plurality of scan driving unit control lines SCL, and the first shielding line SL1 and the second shielding line SL2 may be electrically connected. Furthermore, DC voltage may be applied to the first shielding pattern SP1, the first shielding line SL1 and the second shielding line SL2. The DC voltage may be higher than a minimum voltage applied to the plurality of scan driving unit control lines SCL and lower than a maximum volage applied to the plurality of scan driving unit control lines SLC. Therefore, the first shielding pattern SP1, the first shielding line SL1 and the second shielding line SL2 may be prevented from a possible corrosion problem.

The second shielding pattern SP2 may be spaced apart from the first shielding pattern SP1. The second shielding pattern SP2 may overlap with the plurality of data lines DL, and the third shielding line SL3 and the fourth shielding line SL4 may be electrically connected. In addition, DC voltage may be applied to the second shielding pattern SP2, the third shielding line SL3 and the fourth shielding line SL4. The DC voltage may be higher than a minimum voltage applied to the plurality of data lines DL and lower than a maximum volage applied to the plurality of data lines DC. Accordingly, the second shielding pattern SP2, the third shielding line SL3 and the fourth shielding line SL4 may be prevented from a possible corrosion problem. The third shielding pattern SP3 may be spaced apart from the first shielding pattern SP1 and the second shielding pattern SP2. The third shielding pattern SP3 may overlap with the plurality of input sensor lines ISL, and the fifth shielding line SL5 and the sixth shielding line SL6 may be electrically connected. In addition, DC voltage may be applied to the third shielding pattern SP3, the fifth shielding line SL5 and the sixth shielding line SL6. The DC voltage may be higher than a minimum voltage applied to the plurality of input sensor lines ISL and lower than a maximum volage applied to the plurality of input sensor lines ISL. Therefore, the third shielding pattern SP3, the fifth shielding line SL5 and the sixth shielding line SL6 may be prevented from a possible corrosion problem. The fourth shielding pattern SP4 may be spaced apart from the first shielding pattern SP1, the second shielding pattern SP2 and the third shielding pattern SP3. The fourth shielding pattern SP4 may overlap with the plurality of power lines PL, and the seventh shielding line SL7 and the eighth shielding line SL8 may be electrically connected. In addition, DC voltage may be applied to the fourth shielding pattern SP4, the seventh shielding line SL7 and the eighth shielding line SL8. The DC voltage may be higher than a minimum voltage applied to the plurality of power lines PL and lower than a maximum volage applied to the plurality of power lines PL. Accordingly, the fourth shielding pattern SP4, the seventh shielding line SL7 and the eighth shielding line SL8 may be prevented from a possible corrosion problem. The plurality of power lines PL may be supplied with a direct current power. Accordingly, electromagnetic interference generated from the plurality of power line PL may be relatively low.

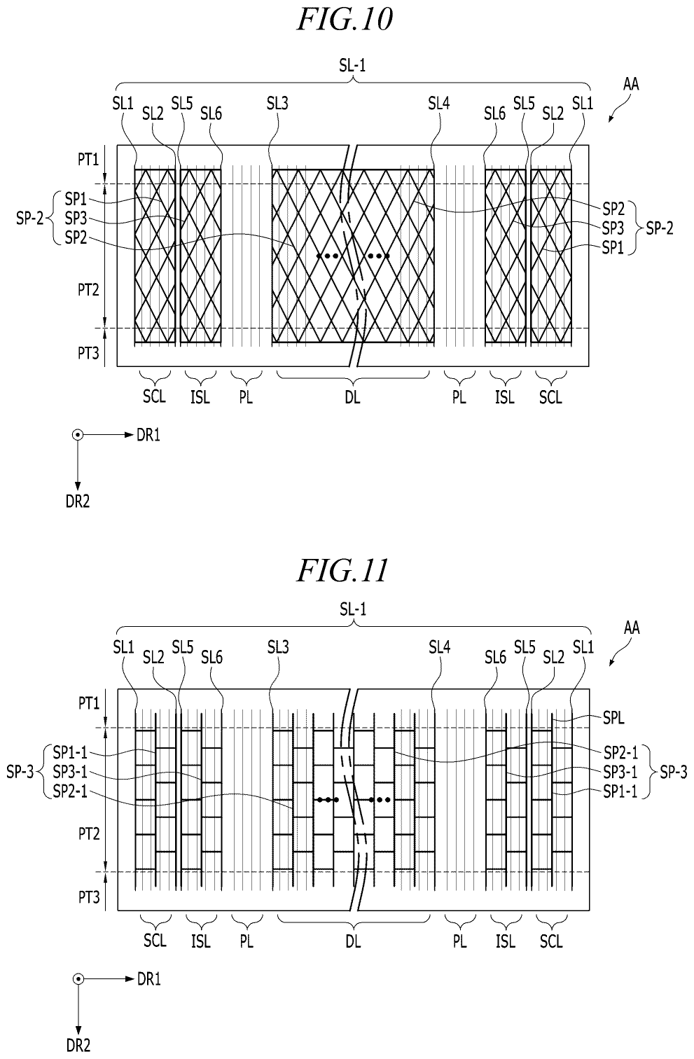

FIG. 10 is an exemplary illustration of a plurality of shielding lines SL-1 and a shielding pattern SP-2 on the same plane in an area corresponding to section AA shown in FIG. 5. Referring to FIG. 10, the shielding pattern SP-2 may include a first shielding pattern SP1, a second shielding pattern SP2 and a third shielding pattern SP3.

In other words, the shielding pattern SP-2 may not overlap with the plurality of power lines PL. In addition, DC voltage may be applied to the plurality of power lines PL so that electromagnetic interference generated from the plurality of power lines PL may be relatively low. Therefore, as the shielding pattern SP-2 has a simple configuration, manufacture cost may be relatively low while the effect may be similar to other shielding patterns.

FIG. 11 is an exemplary illustration of a plurality of shielding lines SL-1 and a shielding pattern SP-3 on the same plane in an area corresponding to section AA shown in FIG. 5. Referring to FIG. 11, the shielding pattern line SPL composing the shielding pattern SP-3 may extend in the first direction DR1 or the second direction DR2.

Accordingly, the shielding pattern line SPL extending in the first direction DR1 may not be applied with tensile stress even in the case where the second area PT2 is bent. Therefore, the shielding pattern line SPL extending in the first direction DR1 may remain undamaged. Therefore, as a portion of the shielding pattern SP-3 including a first shielding pattern SP1-1, a second shielding pattern SP2-1 and a third shielding pattern SP3-1 is undamaged, the shielding pattern SP-3 may not be entirely cut off even in the case where the second area PT2 is bent, and electromagnetic interference may be more reliably blocked.

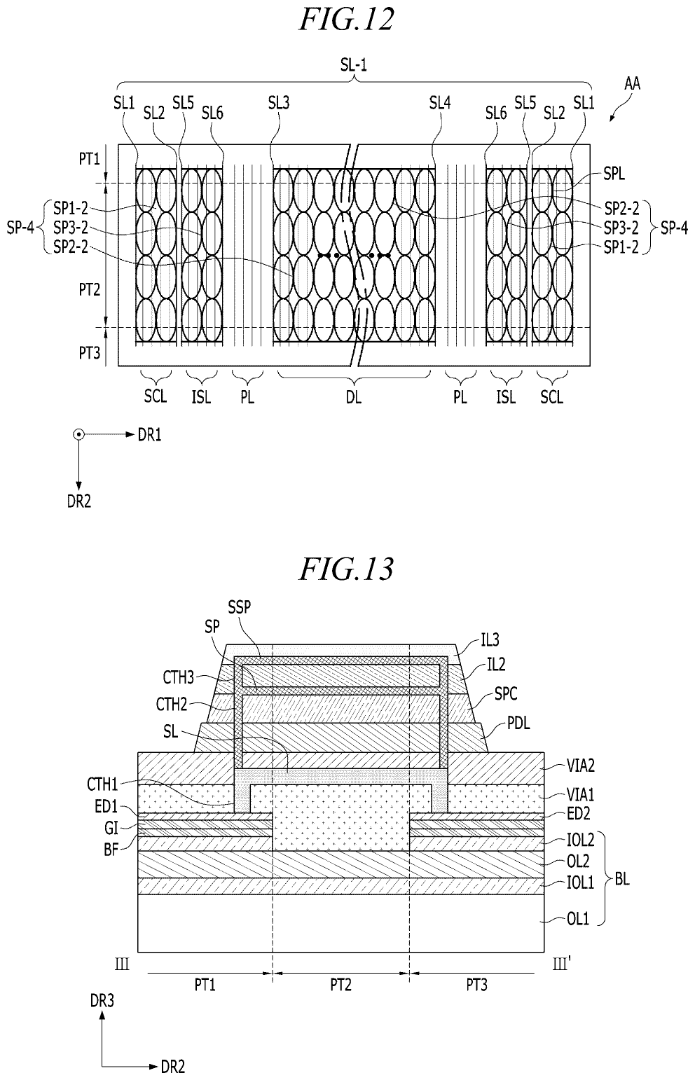

FIG. 12 is an exemplary illustration of a plurality of shielding lines SL-1 and a shielding pattern SP-4 on the same plane in an area corresponding to section AA shown in FIG. 5. Referring to FIG. 12, the shielding pattern SP-4 including a first shielding pattern SP1-2, a second shielding pattern SP2-2 and a third shielding pattern SP3-2 may be formed by repeating elliptical shielding pattern lines SPL.

In addition, when the second area PT2 is bent, the elliptical shielding pattern line SPL may be sealed in the second direction DR2 and contracted in the first direction DR1. Therefore, the elliptical shielding pattern line SPL may be stronger to tensile stress. Therefore, the shielding pattern SP-4 may be stronger to tensile stress. As the result, as the shielding pattern SP-4 is stronger to tensile stress, a damage may be less and electromagnetic interference may be more reliably blocked.

FIG. 13 is an exemplary illustration of a partial cross-section taken along line III-III′ of FIG. 7D. Referring to FIG. 13, the display module DPM may include a second inorganic insulating layer IL2, a sub-shielding pattern SSP, and a third inorganic insulating layer IL3 instead of the inorganic insulating layer IL.

The shielding pattern SP in FIG. 13 may be manufactured through the same process as for the first input sensor electrode ISE1 in FIG. 3. In an embodiment, the shielding pattern SP may be manufactured through a PVD process, for example. In addition, the PVD process may be implemented through a sputtering process.

The second inorganic insulating layer IL2 may cover the shielding pattern SP and overlap with the first area PT1, the second area PT2, and the third area PT3. The second inorganic layer IL2 may be manufactured through a CVD process. The CVD process may be a PECVD process. The second inorganic insulating layer IL2 may be the same as the second inorganic insulating layer IL2 in FIG. 3. In addition, an upper surface of the second inorganic insulating layer IL2 may be defined as a fifth plane, and the fifth plane may correspond to the second area PT2. In addition, the upper surface of the second inorganic insulating layer IL2 may be defined as a plane that is the most distant from the base member BL among the planes composing the second inorganic insulating layer IL2.

In addition, the second inorganic insulating layer IL2 may be defined with a plurality of third contact holes CTH3. The plurality of third contact holes CTH3 may be manufactured through a dry etching process. In addition, the second insulating layer IL2 may be the same as the second inorganic insulating layer IL2 in FIG. 3. The third contact holes CTH3 may overlap with the first area PT1 and the third area PT3.

The sub-shielding pattern SSP may be disposed on the second inorganic insulating layer IL2 and overlap with the second area PT2. In addition, the sub-shielding pattern SSP may be electrically connected to the shielding pattern SP through the plurality of third contact holes CTH3. Particularly, the sub-shielding pattern SSP may extend in a direction of intersection with the fourth plane in the first area PT1 through the plurality of third contact holes CTH3 to contact the shielding pattern SP. In addition, the sub-shielding pattern SSP may extend in a direction of intersection with the fourth plane in the third area PT3 through the plurality of third contact holes CTH3 to contact the shielding pattern SP.

The sub-shielding pattern SSP may be manufactured through the same process as for the second input sensor electrode ISE2 in FIG. 3. In an embodiment, the sub-shielding pattern SSP may be manufactured through a PVD process, for example. In addition, the PVD process may be a sputtering process. The sub-shielding pattern SSP may be merely disposed in a different place from the shielding pattern SP, but have substantially the same configuration as the shielding pattern SP.

The third inorganic insulating layer IL3 may cover the sub-shielding pattern SSP and overlap with the first area PT1, the second area PT2, and the third area PT3. The third inorganic insulating layer IL3 may be manufactured through a CVD process. In addition, the CVD process may be a PECVD process. The third inorganic insulating layer IL3 may be the same as the third inorganic insulating layer IL3 in FIG. 3.

In other words, the sub-shielding pattern SSP may be disposed on the shielding pattern SP. Even in the case where the shielding pattern SP is damaged, the sub-shielding pattern SSP is maintained to block electromagnetic interference, or even in the case where the sub-shielding pattern SSP is damaged, the shielding pattern SP is maintained to block electromagnetic interference. Therefore, electromagnetic interference may be more reliably blocked.

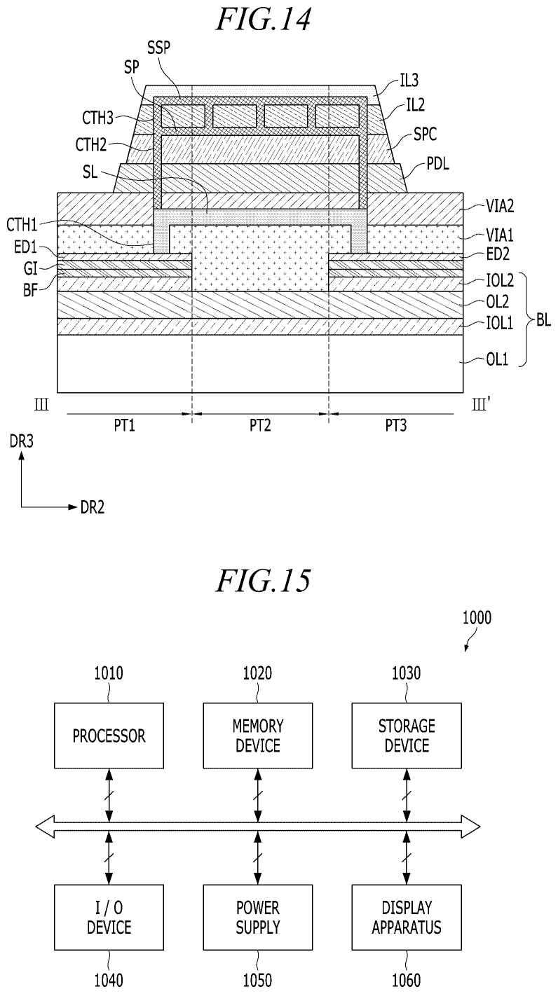

FIG. 14 is an exemplary illustration of a partial cross-section taken along line III-III′ of FIG. 7D. Referring to FIG. 14, the plurality of third contact holes CTH3 disposed on the second inorganic insulating layer IL2 may overlap with the first area PT1, the second area PT2, and the third area PT3 instead of the first area PT1 and the third area PT3. Particularly, the sub-shielding pattern SSP may extend in a direction of intersection with the fourth plane in the first area PT1, the second area PT2, and the third area PT3 through the plurality of third contact holes CTH3 to contact the shielding pattern SP.

Therefore, even in the case where both of the shielding pattern SP and the sub-shielding pattern SSP are damaged, the shielding pattern SP and the sub-shielding pattern SSP may make contact through the plurality of third contact holes CTH3 overlapping with the second area PT2 so that voltage may be possibly applied.

In an embodiment, one of the plurality of third contact holes CTH3 in the shielding pattern may be damaged on the left, and one of the plurality of the plurality of third contact holes CTH3 in the sub-shielding pattern SSP may be damaged on the right, for example. Under the above circumstances, undamaged shielding pattern SP on the right and undamaged sub-shielding pattern SSP on the left may make contact through one of the plurality of third contact holes CTH3 so that voltage may be normally applied. Accordingly, electromagnetic interference may be more reliably blocked.

FIG. 15 is a block diagram illustrating an electronic device according to an embodiment.

Referring to FIG. 15, in an embodiment, an electronic device 1000 may include a processor 1010, a memory device 1020, a storage device 1030, an input/output (“I/O”) device 1040, a power supply 1050, and a display device 1060. Here, the electronic device 1000 may correspond to the electronic device (e.g., display device DD) of FIGS. 1A and 1B. The electronic device 1000 may further include a plurality of ports for communicating with a video card, a sound card, a memory card, a universal serial bus (“USB”) device, or the like. In an embodiment, the electronic device 1000 may be implemented as a television. In another embodiment, the electronic device 1000 may be implemented as a smart phone. However, embodiments are not limited thereto, in another embodiment, the electronic device 1000 may be implemented as a cellular phone, a video phone, a smart pad, a smart watch, a PC, a car navigation system, a computer monitor, a laptop, a head disposed (e.g., mounted) display (“HMD”), or the like.

The processor 1010 may perform various computing functions. In an embodiment, the processor 1010 may be a microprocessor, a central processing unit (“CPU”), an application processor (“AP”), or the like. The processor 1010 may be coupled to other components via an address bus, a control bus, a data bus, or the like. In an embodiment, the processor 1010 may be coupled to an extended bus such as a peripheral component interconnection (“PCI”) bus.

The memory device 1020 may store data for operations of the electronic device 1000. In an embodiment, the memory device 1020 may include at least one non-volatile memory device such as an erasable programmable read-only memory (“EPROM”) device, an electrically erasable programmable read-only memory (“EEPROM”) device, a flash memory device, a phase change random access memory (“PRAM”) device, a resistance random access memory (“RRAM”) device, a nano floating gate memory (“NFGM”) device, a polymer random access memory (“PoRAM”) device, a magnetic random access memory (“MRAM”) device, a ferroelectric random access memory (“FRAM”) device, or the like, and/or at least one volatile memory device such as a dynamic random access memory (“DRAM”) device, a static random access memory (“SRAM”) device, a mobile DRAM device, or the like.

In an embodiment, the storage device 1030 may include a solid state drive (“SSD”) device, a hard disk drive (“HDD”) device, a CD-ROM device, or the like. In an embodiment, the I/O device 1040 may include an input device such as a keyboard, a keypad, a mouse device, a touchpad, a touch-screen, or the like, and an output device such as a printer, a speaker, or the like.

The power supply 1050 may provide power for operations of the electronic device 1000. The power supply 1050 may provide power to the display device 1060. The display device 1060 may be coupled to other components via the buses or other communication links. In an embodiment, the display device 1060 may be included in the I/O device 1040.

In an embodiment the electronic device may be implemented as a smartphone. However the embodiments of the present disclosure may be exemplary and may not be limited to this. For example, the electronic device 1000 may be implemented as a mobile phone, a video phone, a smart pad, a smart watch, a television, a tablet PC, a vehicle display, a computer monitor, a notebook computer, a head-mounted display device, etc. In addition, the electronic device 1000 may be a television, a monitor, a notebook computer, or a tablet. In addition, the electronic device 1000 may be a car.

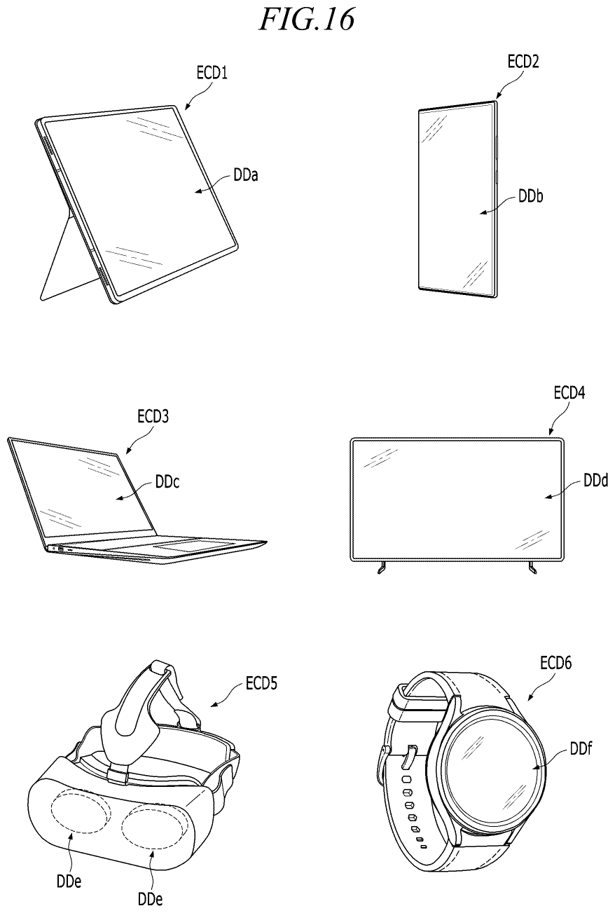

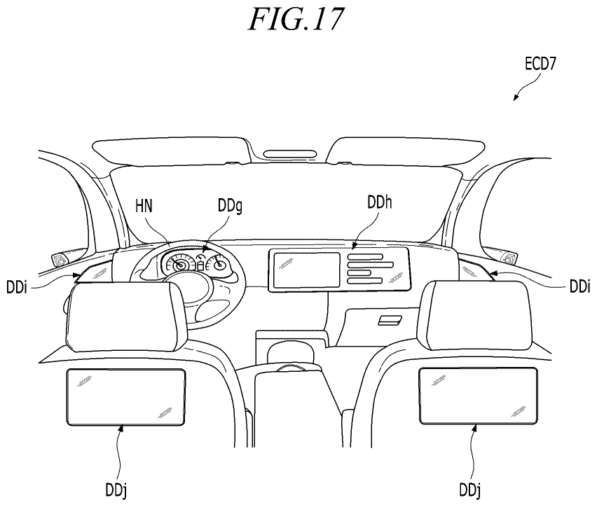

FIGS. 16 and 17 are diagrams illustrating electronic devices to which the display device according to an embodiment of the present disclosure is applied.

Referring to FIG. 16, a first electronic device ECD1 is depicted as a tablet PC including a first display device DDa. A second electronic device ECD2 is depicted as a portable terminal including a second display device DDb. A third electronic device ECD3 is depicted as a notebook computer including a third display device DDc. A fourth electronic device ECD4 is depicted as a TV including a fourth display device DDd. A fifth electronic device ECD5 is depicted as a head-mounted display device including a fifth display device DDe. A sixth electronic device ECD6 is depicted as a digital watch including a sixth display device DDf.

Referring to FIG. 17, a seventh electronic device ECD7 is depicted as a vehicle including seventh through tenth display devices DDg-DDj. Although an automobile is exemplified as the seventh electronic device ECD7, the present disclosure is not limited thereto and may include various types of transportation means, such as bicycles, motorcycles, trains, ships, and airplanes.

The seventh display device DDg may be placed in front of the steering wheel HN within the driver's field of view and may be used to display dashboard information such as vehicle speed. The eighth display device DDh may be separate from the seventh display device DDg and placed on the vehicle's dashboard to display control interfaces, audio, temperature, road conditions, and videos. The ninth display device DDi may be placed at the driver and passenger side mirrors and may be utilized as a digital side mirror. The ninth display device DDi may display video captured from the vehicle's exterior. The tenth display device DDj may be placed behind the driver and passenger seats and may display contents, such as videos, to the rear seat passengers.

At least one of the first through tenth display devices DDa-DDj may include the display device DD described with reference to FIGS. 1A to 1B, FIGS. 2A to 2B, FIGS. 3 to 6, FIGS. 7A to 7D and FIG. 8. At least one of the first through tenth display devices DDa-DDj may also include the display device DD described with reference to FIG. 9 or FIG. 14.

The display devices according to embodiments of the present disclosure are not limited to the electronic devices shown in FIGS. 16 and 17 and may also be applied to a variety of electronic devices, such as printers, telephones, wearable devices, digital cameras, camcorders, viewfinders, 3D displays, video walls comprising tiled displays, theaters, signage, and the like.

While illustrative embodiments of the disclosure have been described above, anyone ordinarily skilled in the art to which the disclosure pertains shall appreciate that there may be a variety of modifications and permutations of the disclosure without departing from the technical ideas and scopes of the disclosure that are defined in the appended claims. Moreover, it shall be appreciated that the disclosed embodiments are not intended to restrict the disclosure thereto and that every technical idea within the appended claims and their equivalents is interpreted to be included in the scope of the disclosure.

What is claimed is:

1. A display module including:
a base member defined with a first area including a display area and a non-display area surrounding the display area, a second area extending from the first area, and a third area extending from the second area, the second area being bent;
a plurality of light-emitting components disposed on the base member and overlapping with the display area;
a plurality of first lines disposed on the base member and overlapping with the first area;
a plurality of second lines disposed on the base member and overlapping with the third area, each corresponding to the plurality of first lines;
a first circuit insulating layer disposed on the base member, configured to cover the plurality of first lines and the plurality of second lines, overlapping with the first area, the second area, and the third area and defined with a plurality of first contact holes;
a plurality of shielding lines manufactured on the first circuit insulating layer through a physical vapor deposition process, overlapping with the second area and configured to electrically connect the plurality of first lines to the plurality of second lines through the plurality of first contact holes respectively;
a second circuit insulating layer disposed on the first circuit insulating layer, configured to cover the plurality of shielding lines, overlapping with the first area, the second area, and the third area, and defined with a plurality of second contact holes; and
a shielding pattern manufactured on the second circuit insulating layer through a physical vapor deposition process, overlapping with the second area and electrically connected to the plurality of shielding lines through the plurality of second contact holes.

2. The display module of claim 1,
wherein some second contact holes of the plurality of second contact holes overlap with the first area and remaining second contact holes overlap with the third area.

3. The display module of claim 1, further comprising a plurality of input sensor electrodes disposed on the plurality of light-emitting components,
wherein two input sensor electrodes next to each other among the plurality of input sensor electrodes form a capacitor, and
wherein a material contained in each of the plurality of input sensor electrodes is identical to a material contained in the shielding pattern.

4. The display module of claim 3, further comprising:
a plurality of pixel circuits electrically connected to the plurality of light-emitting components;
a scan driving unit configured to provide a scan signal to the plurality of pixel circuits;
a plurality of scan driving control lines configured to transfer an electric signal for controlling the scan driving unit;
a plurality of data lines configured to transfer a data signal to the plurality of pixel circuits;
a plurality of power lines configured to transfer power to the plurality of pixel circuits; and
a plurality of input sensor lines electrically connected to the plurality of input sensor electrodes,
wherein the shielding pattern overlap with at least one of the plurality of scan driving control lines, the plurality of data lines and the plurality of input sensor lines.

5. The display module of claim 4,
wherein the shielding pattern does not overlap with the plurality of power lines.

6. The display module of claim 4,
wherein the plurality of shielding lines comprises:
a first shielding line;
a second shielding line disposed parallel to the first shielding line to have the plurality of scan driving control lines interposed therebetween;
a third shielding line spaced apart from the second shielding line;
a fourth shielding line disposed parallel to the third shielding line to have the plurality of data lines interposed therebetween;
a fifth shielding line spaced apart from the shielding line; and
a sixth shielding line disposed parallel to the fifth shielding line to have the plurality of input sensor lines interposed therebetween.

7. The display module of claim 6,
wherein the shielding pattern comprises:
a first shielding pattern overlapping with the plurality of scan driving control lines;
a second shielding pattern overlapping with the plurality of data lines and spaced apart from the first shielding pattern; and
a third shielding pattern overlapping with the plurality of input sensor lines and spaced apart from the first shielding pattern and the second shielding pattern.

8. The display module of claim 7,
wherein voltage applied to the first shielding pattern is higher than minimum voltage applied to the plurality of scan driving control lines and lower than maximum voltage applied to the plurality of scan driving control lines,
wherein voltage applied to the second shielding pattern is higher than minimum voltage applied to the plurality of data lines and lower than maximum voltage applied to the plurality of data lines, and
wherein voltage applied to the third shielding pattern is higher than minimum voltage applied to the plurality of input sensor lines and lower than maximum voltage applied to the plurality of input sensor lines.

9. The display module of claim 4,
wherein each of the plurality of pixel circuits comprises a transistor comprising a first electrode, a second electrode and a control electrode,
wherein a material contained in each of the first electrode and the second electrode is identical to a material contained in each of the plurality of shielding lines.

10. The display module of claim 1,
wherein the shielding pattern includes a plurality of shielding pattern lines, and
wherein each of the plurality of shielding pattern lines has at least a portion extending in an intersection direction intersecting with the plurality of shielding lines.

11. The display module of claim 1, further comprising:
an inorganic insulating layer configured to cover the shielding pattern, overlapping with the first area, the second area, and the third area, and defined with a plurality of third contact holes; and
a sub-shielding pattern manufactured on the inorganic insulating layer through a physical vapor deposition process on the inorganic insulating layer, overlapping with the second area and electrically connected to the shielding pattern through the plurality of third contact holes,
wherein the plurality of third contact holes overlap with at least one of the first area, the second area, and the third area.

12. A display module comprising:
a base member defined with a first area including a display area and a non-display area surrounding the display area; a second area extending from the first area and a third area extending from the second area;
a plurality of light-emitting components disposed on the base member and overlapping with the display area;
a plurality of first lines disposed on the base member and disposed on a first plane parallel to the first area, the first plane corresponding to the first area;
a plurality of second lines disposed on the base member and disposed on a second plane parallel to the third area, the second plane corresponding to the third area, each corresponding to the plurality of first lines;
a plurality of shielding lines manufactured on a third plane on the first plane through a physical vapor deposition process and configured to electrically connect the plurality of first lines to the plurality of second lines, respectively, the third plane corresponding to the second area; and
a shielding pattern manufactured on a fourth plane on the third plane through a physical vapor deposition process and electrically connected to the plurality of shielding lines, the fourth plane corresponding to the second area.

13. The display module of claim 12,
wherein the shielding pattern extends in an intersection direction intersecting with the third plane in the first area to contact the plurality of shielding lines, and
wherein the shielding pattern extends in the intersection direction intersecting with the third plane in the third area to contact the plurality of shielding lines.

14. The display module of claim 12, further comprising a plurality of input sensor electrodes disposed on the plurality of light-emitting components,
wherein two input sensor electrodes next to each other among the plurality of input sensor electrodes form a capacitor, and
wherein a material contained in each of the plurality of input sensor electrodes is identical to a material contained in the shielding pattern.

15. The display module of claim 14, further comprising:
a plurality of pixel circuits electrically connected to the plurality of light-emitting components;
a scan driving unit configured to provide a scan signal to the plurality of pixel circuits;
a plurality of scan driving control lines configured to transfer an electric signal for controlling the scan driving unit;
a plurality of data lines configured to transfer a data signal to the plurality of pixel circuits;
a plurality of power lines configured to transfer power to the plurality of pixel circuits; and
a plurality of input sensor lines electrically connected to the plurality of input sensor electrodes,
wherein the shielding pattern overlaps with at least one of the plurality of scan driving control lines, the plurality of data lines and the plurality of input sensor lines.

16. The display module of claim 15,
wherein the plurality of shielding lines comprises:
a first shielding line;
a second shielding line disposed parallel to the first shielding line to have the plurality of scan driving control lines interposed therebetween;
a third shielding line spaced apart from the second shielding line;
a fourth shielding line disposed parallel to the third shielding line to have the plurality of data lines interposed therebetween;
a fifth shielding line spaced apart from the fourth shielding line; and
a sixth shielding line disposed parallel to the fifth shielding line to have the plurality of input sensor lines interposed therebetween,
wherein the shielding pattern does not overlap with the plurality of power lines, and
wherein the shielding pattern comprises:
a first shielding pattern overlapping with the plurality of scan driving control lines;
a second shielding pattern overlapping with the plurality of data lines and spaced apart from the first shielding pattern; and
a third shielding pattern overlapping with the plurality of input sensor lines and spaced apart from the first shielding pattern and the second shielding pattern.

17. The display module of claim 15,
wherein each of the plurality of pixel circuits comprises a transistor comprising a first electrode, a second electrode, and a control electrode, and
wherein a material contained in each of the first electrode and the second electrode is identical to a material contained in each of the plurality of shielding lines.

18. The display module of claim 12,
wherein the shielding pattern comprises a plurality of shielding pattern lines, and
wherein each of the plurality of shielding pattern lines has at least a portion extending in a direction intersecting with the plurality of shielding lines.

19. The display module of claim 12, further comprising a sub-shielding pattern manufactured through a physical vapor deposition process in a fifth plane defined on the fourth plane, corresponding to the second area and electrically connected to the shielding pattern,
wherein the sub-shielding pattern extends in a direction intersecting with the fourth plane in at least one area of the first area, the second area, and the third area to contact the shielding pattern.

20. An electronic device comprising:
a display module comprising:
a base member defined with a first area comprising a display area and a non-display area surrounding the display area; a second area extending from the first area and a third area extending from the second area, the second area being bent;
a plurality of light-emitting components disposed on the base member and overlapping with the display area;
a plurality of first lines disposed on the base member and overlapping with the first area;
a plurality of second lines disposed on the base member and overlapping with the third area, each corresponding to the plurality of first lines;
a first circuit insulating layer disposed on the base member, configured to cover the plurality of first lines and the plurality of second lines, overlapping with the first area, the second area and the third area, and defined with a plurality of first contact holes;
a plurality of shielding lines manufactured on the first circuit insulating layer through a physical vapor deposition process, overlapping with the second area, and configured to electrically connect the plurality of first lines to the plurality of second lines, respectively, through the plurality of first contact holes;
a second circuit insulating layer disposed on the first circuit insulating layer, configured to cover the plurality of shielding lines, overlapping with the first area, the second area and the third area, and defined with a plurality of second contact holes; and
a shielding pattern manufactured on the second circuit insulating layer through a physical vapor deposition process, overlapping with the second area, and electrically connected to the plurality of shielding lines through the plurality of second contact holes;
a communication module;
a power module configured to provide power to the display module and the communication module; and
a housing configured to house the display module, the communication module, and the power module,
wherein the plurality of shielding lines and the shielding pattern are interposed between the communication module and the base member.
